(19) United States
(12) Patent Application Publication
(10) Pub. No.: US 2025/0220969 A1
(43) Pub. Date: Jul. 3, 2025

(54) GATE-ALL-AROUND DEVICES WITH DIFFERENT GATE LENGTHS

(71) Applicant: Intel Corporation, Santa Clara, CA (US)

(72) Inventors: Shao Ming Koh, Tigard, CA (US); Chang Wan Han, Portland, OR (US); Clifford L. Ong, Portland, OR (US); Vishal Tiwari, Hillsboro, OR (US); Sudipto Naskar, Portland, OR (US); Vivek Thirtha, Portland, OR (US); Seenivasan Subramaniam, Hillsboro, OR (US); Glenn Glass, Portland, OR (US); Sameerah Desnavi, Hillsboro, OR (US); Chandra Mouli Palit, Portland, OR (US); Jinwoo Lee, Portland, OR (US)

(21) Appl. No.: 18/399,297

(22) Filed: Dec. 28, 2023

(51) Int. Cl. H01L 29/423; H01L 27/092; H01L 29/06; H01L 29/417; H01L 29/66; H01L 29/778

(52) U.S. Cl. CPC H10D 30/6735; H10D 30/47; H10D 30/6729; H10D 62/118; H10D 64/021; H10D 84/85

(57) ABSTRACT

Techniques are provided herein to form semiconductor devices having different gate lengths on the same die. In an example, any number of first semiconductor devices includes first gate structures around first semiconductor regions and any number of second semiconductor devices include second gate structures around second semiconductor regions. The first gate structures have a first gate length around the first semiconductor regions and the second gate structures have a second gate length around the second semiconductor regions with the second gate length being greater than the first gate length. An upper thickness of each the first and second gate structures may be the same, despite the gate length diversity. The first semiconductor devices include first inner spacer structures around ends of the first semiconductor regions that have a greater lateral thickness compared to second inner spacer structures around ends of the second semiconductor regions of the second semiconductor devices.

### BACKGROUND

As integrated circuits continue to scale downward in size, a number of challenges arise. For instance, reducing the size of memory and logic cells is becoming increasingly more difficult. Different transistor architectures that maximize available semiconductor surfaces to form active channels have been contemplated, including gate-all-around and forksheet architectures. However, such architectures come with drawbacks with regards to the small dimensions between the semiconductor regions. It can be challenging to adjust the dimensions of certain transistor elements between different transistors on the same die. Accordingly, there remain a number of non-trivial challenges with respect to forming certain transistor structures.

### BRIEF DESCRIPTION OF THE DRAWINGS

FIG. 1A is a cross-sectional view of a pair of semiconductor devices having a first gate length, in accordance with an embodiment of the present disclosure.

FIG. 1B is a cross-sectional view of another pair of semiconductor devices having a second gate length greater than the first gate length, in accordance with an embodiment of the present disclosure.

FIG. 1C is a plan view of a portion of an integrated circuit that includes the pair of semiconductor devices from FIG. 1A and the pair of semiconductor devices from FIG. 1B.

FIGS. 2A and 2B are cross-sectional views that illustrate one stage in an example process for forming an integrated circuit configured with one or more devices having a first gate length and one or more devices having a second gate length different from the first gate length, in accordance with an embodiment of the present disclosure.

FIGS. 3A and 3B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 4A and 4B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 5A and 5B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 6A and 6B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 7A and 7B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 8A and 8B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 9A and 9B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 10A and 10B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 11A and 11B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 12A and 12B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 13A and 13B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 14A and 14B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 15A and 15B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 16A and 16B are cross-sectional views that illustrate another stage in the example process for forming an integrated circuit configured with one or more devices having a first gate length and one or more devices having a second gate length different from the first gate length, in accordance with an embodiment of the present disclosure.

FIGS. 17A and 17B are cross-sectional views that illustrate another stage in the example process for forming an integrated circuit configured with one or more devices having a first gate length and one or more devices having a second gate length different from the first gate length, in accordance with an embodiment of the present disclosure.

FIG. 18 illustrates a cross-sectional view of a chip package containing one or more semiconductor dies, in accordance with some embodiments of the present disclosure.

FIG. 19 is a flowchart of a fabrication process for an integrated circuit having semiconductor devices with different gate lengths, in accordance with an embodiment of the present disclosure.

FIG. 20 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices having different gate lengths on the same die. The techniques can be used in any number of integrated circuit applications and are particularly useful with respect to gate-all-around (GAA) transistors (e.g., ribbonFETs and nanowire FETs). In an example, any number of first semiconductor devices includes first gate structures around first semiconductor regions and any number of second semiconductor devices include second gate structures around second semiconductor regions. The first and second semiconductor regions can be or one or more nanowires or nanoribbons or nanosheets of semiconductor material that extend between corresponding source and drain regions. The first and second gate structures include a gate dielectric and a gate electrode (e.g., conductive material such as workfunction material and/or gate fill metal) on the gate dielectric. According to some embodiments, the first gate structures have a first gate length around the first semiconductor regions and the second gate structures have a second gate length around the second semiconductor regions with the second gate length being greater than the first gate length. The second gate length may be at least 4 nm greater than the first gate length. Gate length corresponds to the length of semiconductor material extending from a source region to a drain region and that is covered (wrapped) by the given gate structure. The first semiconductor devices include first inner spacer structures around ends of the first semiconductor regions that have a greater lateral thickness compared to second inner spacer structures around ends of the second semiconductor regions of the second semiconductor devices. The first inner spacers may have a lateral thickness that is at least 2 nm greater than the lateral thickness of the second inner spacers. This difference in inner spacer thickness can be used to provide the difference in gate length, as further described below. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. GAA devices provide efficient use of limited chip footprint by providing several semiconductor regions (e.g., nanoribbons) in a single device. However, making changes to the geometry of certain structures across a given die can be challenging. For example, it may be beneficial to include transistors having different gate lengths on the same die. Some applications, like memory applications, may benefit from transistors with larger gate lengths while other applications, like logic circuits, may benefit from transistors with smaller gate lengths. Additionally, p-type transistors (PMOS) may benefit from having a larger gate length compared to n-type transistors (NMOS). Incorporating transistors of different gate lengths can be achieved by printing gate lines having different widths, but this adds to complexity and cost when designing densely packed devices on a die.

Thus, and in accordance with an embodiment of the present disclosure, techniques are provided herein to form GAA semiconductor devices with different gate lengths. In an example, one or more first GAA devices include a first gate length and one or more second GAA devices on the same substrate include a second gate length that is greater than the first gate length. Rather than pattern gates having different pitches, gates are formed that have the same pitch and the thickness of inner spacer structures are changed to control the gate length over the semiconductor regions of the devices, according to some embodiments.

In some such examples, the one or more first GAA devices have inner spacer structures that have a lateral thickness that are at least 2 nm greater than a lateral thickness of the inner spacer structures of one or more second GAA devices on the same die. Decreasing the inner spacer thickness results in a corresponding widening of the gate along the lengths of the nanoribbons, according to some embodiments. Thus, in this example case, the one or more second GAA devices may have a gate length that is around 4 nm or more greater than the gate length of the one or more first GAA devices. Variations in dimensions of the inner spacer structures may be used to form various GAA devices on the same die having any number of different gate lengths.

According to an embodiment, an integrated circuit includes a first semiconductor device having at least one first semiconductor body extending in a first direction from a first source or drain region, a first gate structure extending in a second direction over the first semiconductor body and wrapped around the first semiconductor body, and at least one first dielectric spacer between the first gate structure and the first source or drain region. The integrated circuit also includes a second semiconductor device having at least one second semiconductor body extending in the first direction from a second source or drain region, a second gate structure extending in the second direction over the at least one second semiconductor body and wrapped around the second semiconductor body, and at least one second dielectric spacer between the second gate structure and the second source or drain region. The at least one first dielectric spacer is at least 2 nm longer than the at least one second dielectric spacer along the first direction.

According to another embodiment, an integrated circuit includes a first semiconductor device having a plurality of first semiconductor nanoribbons extending in a first direction from a first source or drain region to a second source or drain region, a first gate structure extending in a second direction over the plurality of first semiconductor nanoribbons, and a plurality of first dielectric spacers between the first gate structure and the first source or drain region and between the first gate structure and the second source or drain region. The integrated circuit also includes a second semiconductor device having a plurality of second semiconductor nanoribbons extending in the first direction from a third source or drain region to a fourth source or drain region, a second gate structure extending in the second direction over the plurality of second semiconductor nanoribbons, and a plurality of second dielectric spacers between the second gate structure and the third source or drain region and between the second gate structure and the fourth source or drain region. The plurality of first dielectric spacers are at least 2 nm longer than the plurality of second dielectric spacers along the first direction.

According to another embodiment, a method of forming an integrated circuit includes forming a first fin comprising first semiconductor layers alternating with first sacrificial layers, the first fin extending above a substrate and extending in a first direction; forming a second fin comprising second semiconductor layers alternating with second sacrificial layers, the second fin extending above a substrate and extending in the first direction; forming a dielectric structure over the first fin and the second fin; forming a mask structure over the second fin; removing a portion of the dielectric structure and a portion of the first fin such that the first semiconductor layers alternating with first sacrificial layers are exposed; performing a first etch process to laterally recess the first sacrificial layers and form first laterally recessed areas having a first recess depth along the first direction; forming first dielectric spacer structures within the first laterally recessed areas; forming a first source or drain region from exposed ends of the first semiconductor layers; removing the mask structure over the second fin; removing a portion of the dielectric structure and a portion of the second fin such that the second semiconductor layers alternating with second sacrificial layers are exposed; performing a second etch process to laterally recess the second sacrificial layers and form second laterally recessed areas having a second recess depth along the first direction that is different from the first recess depth by at least 2 nm; forming second dielectric spacer structures within the second laterally recessed areas; and forming a second source or drain region from exposed ends of the second semiconductor layers.

The techniques can be used with any type of non-planar transistors, but are especially useful for nanowire and nanoribbon transistors (sometimes called GAA transistors) or nanosheet transistors (sometimes called forksheet transistors), to name a few examples. The source and drain regions can be, for example epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate one or more GAA devices having laterally longer inner spacer structures (e.g., at least 2 nm longer along the channel direction) compared to other GAA devices. In some examples, the GAA devices having the longer inner spacer structures have correspondingly shorter gate lengths along the channel compared to the GAA devices with the laterally shorter inner spacer structures. In some examples, the GAA devices may each have a same upper gate thickness that is laterally between source and drain contacts, despite some of those devices having a different lower gate thickness that is laterally between source and drain regions. In some such cases, the upper gate thickness of all the GAA devices is smaller (e.g., at least 4 nm smaller) than the lower gate thickness of the GAA devices with the laterally shorter inner spacer structures.

It should be readily understood that the meaning of “above” and “over” in the present disclosure should be interpreted in the broadest manner such that “above” and “over” not only mean “directly on” something but also include the meaning of over something with an intermediate feature or a layer therebetween. As used herein, the term “backside” generally refers to the area beneath one or more semiconductor devices (below the device layer) either within the device substrate or in the region of the device substrate (in the case where the bulk of the device substrate has been removed). Note that the backside may become a frontside, and vice-versa, if a given structure is flipped. To this end, and as will be appreciated, the use of terms like “above” “below” “beneath” “upper” “lower” “top” and “bottom” are used to facilitate discussion and are not intended to implicate a rigid structure or fixed orientation; rather such terms merely indicate spatial relationships when the structure is in a given orientation.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

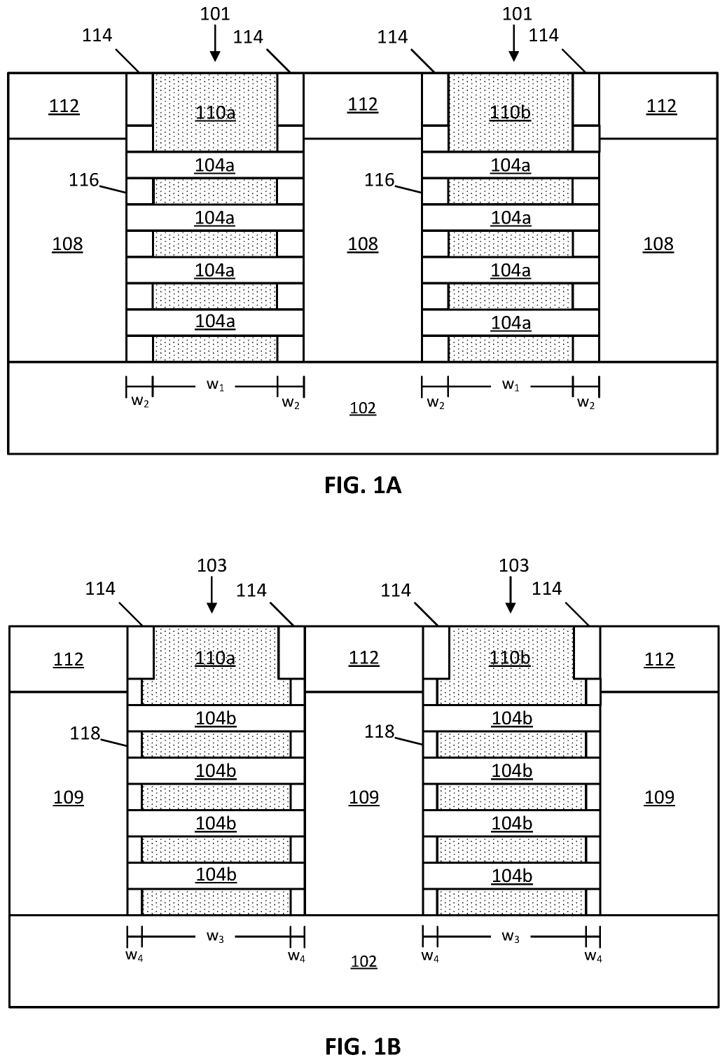

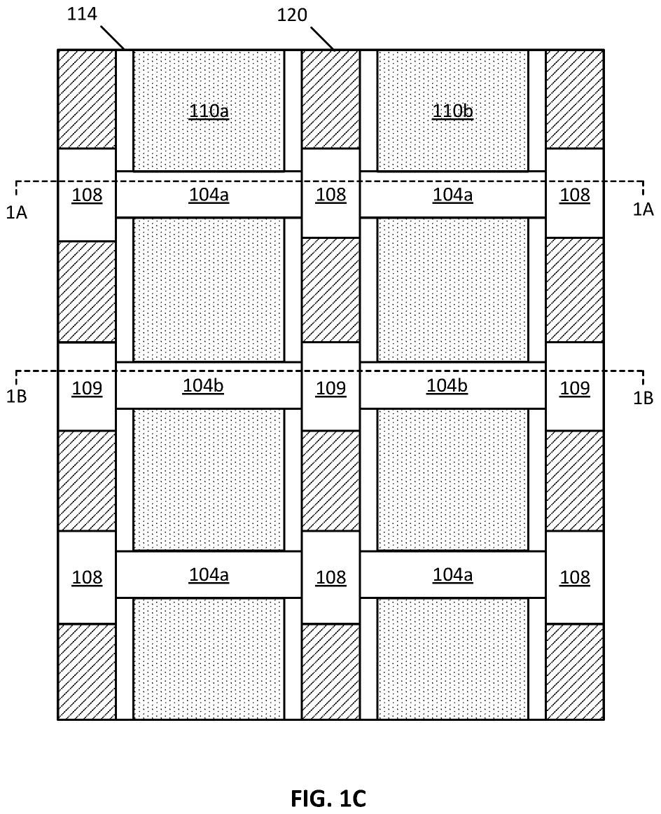

FIG. 1A is a cross-sectional view taken across a pair of first semiconductor devices 101 and FIG. 1B is a cross-sectional view taken across a pair of second semiconductor devices 103, according to an embodiment of the present disclosure. Each of first and second semiconductor devices 101 and 103 may be gate-all-around (GAA) or forksheet transistor devices, although other transistor topologies and types could also benefit from the techniques provided herein. The illustrated embodiments herein use the GAA structure.

First and second semiconductor devices 101 and 103 together represent a portion of an integrated circuit that may contain any number of similar semiconductor devices. First and second semiconductor devices 101 and 103 could exist anywhere within the integrated circuit (on the same die) and may extend adjacent and parallel to one another along a first direction.

As can be seen, semiconductor devices 101 and 103 are formed on a same substrate 102 (or die). Any number of other semiconductor devices can be formed on substrate 102. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, substrate 102 is removed from the backside and replaced with one or more dielectric layers along with conductive layers to form backside contacts and backside interconnect layers, such as a power delivery network.

First semiconductor devices 101 may include any number of semiconductor nanoribbons 104a while second semiconductor device 103 similarly may include any number of semiconductor nanoribbons 104b. Nanoribbons 104a may extend between source or drain regions 108 along a first direction (e.g., across the page). Likewise, nanoribbons 104b may extend between source or drain regions 109 along the first direction. Any source region may also act as a drain region and vice versa, depending on the application. Nanoribbons 104a and 104b can also be nanowires or nanosheets or other such semiconductor bodies and may have any number of geometries, such as circular, square, rectangular, or pancake-like (rectangular shape that is elongated into and out of page and relatively short up and down the page).

In some embodiments, semiconductor devices 101 and 103 have an equal number of nanoribbons, while in other embodiments they have an unequal number of nanoribbons. For instance, the example shown includes four nanoribbons in each channel region, but other examples may include one, two or three nanoribbons (or other semiconductor bodies). Also, some channel regions may have fewer bodies than other channel regions, such as may be accomplished via a depopulation process that removes one or more bodies within the channel region during gate processing. In some embodiments, each of nanoribbons 104a and nanoribbons 104b are formed from a fin of alternating material layers (e.g., alternating layers of silicon and silicon germanium) where sacrificial material layers are removed between nanoribbons 104a and nanoribbons 104b. In other embodiments, each of nanoribbons 104a and nanoribbons 104b may include the same semiconductor material as substrate 102, or another material layered on top of substrate 102. In still other cases, substrate 102 is removed. In some such example cases, there may be, for example one or more backside interconnect and/or contact layers.

According to some embodiments, source or drain regions 108/109 are epitaxial regions that are provided using an etch-and-replace process. Any semiconductor materials suitable for source and drain regions can be used (e.g., group IV and group III-V semiconductor materials). The source or drain regions may include multiple layers such as liners and capping layers to improve contact resistance and/or adhesion. In any such cases, the composition and doping of the source or drain regions 108/109 may be the same or different, depending on factors such as the polarity of the transistors and the given circuit application. Any number of source and drain configurations and materials can be used. In some examples, source or drain regions 108 represent n-type source or drain regions (e.g., silicon doped with phosphorous) while source or drain regions 109 represent p-type source or drain regions (e.g., silicon germanium doped with boron), or vice versa.

According to some embodiments, the fin structures include alternating layers of material (e.g., alternating layers of silicon and silicon germanium (SiGe)) that facilitates forming of nanoribbons (or nanowires or nanosheets, as the case may be) during a gate forming process where one type of the alternating layers is selectively etched away so as to liberate the other type of alternating layers within the channel region, so that a gate-all-around (GAA) process flow can then be carried out. In other examples, a forksheet process flow may be used, and the techniques described herein can also be beneficially applied to that process flow to provide gate length diversity, as further described below. The alternating layers can be blanket deposited and then etched into fin structures or deposited into fin-shaped trenches.

According to some embodiments, a first gate structure 110a extends along a second direction into and out of the page over a first set of nanoribbons 104a and a first set of nanoribbons 104b. Similarly, a second gate structure 110b extends along the second direction over a second set of nanoribbons 104a and a second set of nanoribbons 104b. The second direction may be substantially orthogonal (e.g., 90 degrees, plus or minus a degree or two) to the first direction. According to some embodiments, each of the first and second gate structures 110a/110b includes a gate dielectric and a gate electrode. The gate dielectric may include any suitable dielectric material such as silicon dioxide and/or hafnium oxide. In some examples, the gate dielectric includes high-k material having a dielectric constant greater than 6.5. Some example high-k materials include hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

According to some embodiments, the gate electrodes of first and second gate structures 110a/110b may include any sufficiently conductive material such as a metal or metal alloy (e.g., tungsten or tungsten nitride), or polysilicon. According to some embodiments, the gate electrodes may be interrupted between any other semiconductor devices by a gate cut structure, such that gate structure 110a of FIG. 1A is not coupled to gate structure 110a of FIG. 1B and/or gate structure 110b of FIG. 1A is not coupled to gate structure 110b of FIG. 1B. In some embodiments, the gate electrodes include one or more work function metals on the gate dielectric and around the corresponding nanoribbons. For example, a p-channel device may include a work function metal having titanium on the gate dielectric and around the nanoribbons of the p-channel device. In another example, an n-channel device may include a work function metal having tungsten on the gate dielectric and around nanoribbons of the n-channel device. In some embodiments, the gate electrodes each includes a fill metal or other conductive material on the work function metal(s) to provide the whole gate electrode structure.

A conductive contact 112 may be formed over any of source or drain regions 108/109 to provide electrical connections to the corresponding source or drain regions. Conductive contact 112 can include any suitable conductive material, such as tungsten, copper, cobalt, titanium, ruthenium, tantalum, or molybdenum, or alloys of any of these. Contacts 112 may also include multiple layers, such as barrier and/or liner layers to inhibit electromigration and/or improve adhesion and contact resistance (e.g., layer of tantalum, titanium, or nitrides of same).

According to some embodiments, gate spacer structures 114 are present on sidewalls of gate structures 110a/110b to separate the gate structures from the source/drain trenches. Accordingly, gate spacer structures 114 extend along the second direction with gate structures 110a/110b. Spacer structures 114 may include any suitable dielectric material, such as silicon nitride or silicon oxynitride, and may include multiple layers such as a first layer of silicon nitride and a second layer of silicon dioxide on the layer of silicon nitride.

As further shown in the example case of FIGS. 1A and 1B, semiconductor devices 101 include first inner spacers 116 around the ends of nanoribbons 104a, and second semiconductor devices 103 include second inner spacers 118 around the ends of nanoribbons 104b. First and second inner spacers 116/118 may include the same dielectric material as gate spacer structures 114 or may include any other suitable dielectric material. According to some embodiments, the lateral dimension of first and second inner spacers 116/118 along the first direction directly affects the gate length of the transistors. The gate length corresponds to the length of semiconductor material extending from a source region to a drain region and that is covered (wrapped) by the gate structure. For example, first semiconductor devices 101 have a gate length w₁ (which corresponds to the length of gate structures 110a/110b around nanoribbons 104a, in this example), with a first inner spacer width w₂, and second semiconductor devices 103 have a gate length w₃ (which corresponds to the length of gate structures 110a/110b around nanoribbons 104b, in this example), with a second inner spacer width w₄. According to some embodiments, second semiconductor devices 103 have a larger gate length w₃ compared to the gate length w₁ of first semiconductor devices 101 because second inner spacers 118 have a thinner width w₄ compared to the width w₂ of first inner spacers 116. For example, the width w₂ of first inner spacer 116 may be purposefully at least 1 nm, at least 2 nm, or at least 3 nm larger than the width w₄ of second inner spacer 118. Similarly, the gate length w₃ of the gate structures of second semiconductor devices 103 may be purposefully at least 2 nm, 3 nm, at least 4 nm, or at least 5 nm greater than the gate length w₁ of the gate structures of first semiconductor devices 101. According to some embodiments, the gate length w₁ of first semiconductor devices 101 may be between about 12 nm and about 18 nm and the gate length w₃ of second semiconductor devices 103 may be between about 16 nm and about 22 nm. The width w₂ of first inner spacers 116 may be between about 5 nm and about 7 nm and the width w₄ of second inner spacers 118 may be between about 3 nm and about 5 nm. In some cases, the gate electrodes of gate structures 110a/110b directly contact both the left and right side inner spacers 116/118, with no gate dielectric therebetween. In some other cases, the gate dielectric of gate structures 110a/110b extends along the gate-side of the inner spacers 116/118 such that the corresponding gate electrodes do not directly contact the left and ride side inner spacers 116/118. Thus, the gate length may include a length of gate electrode material only, or a length that includes both gate electrode and gate dielectric materials.

FIG. 1C provides a plan view of a portion of the integrated circuit taken across a given layer of nanoribbons 104a/104b. The cross-section of FIG. 1A is taken across the 1A dashed line and the cross-section of FIG. 1B is taken across the 1B dashed line. As shown is this example of FIG. 1C, the pitch of the patterned gates does not change between first and second semiconductor devices 101 and 103, such that w₁+w₂ is substantially equal to w₃+w₄. In such an example, each of gate structures 110a and 110b of devices 101 and 103 has a substantially same thickness along the first direction and laterally between its neighboring contacts 112 (e.g., all such thicknesses are within 10 angstroms of each other), but still have gate length diversity along the first direction down lower in the channel region (e.g., w₁ and w₃ are 3 nm or more different from one another). The length of first and second gate structures 110a/110b (along the first direction) may be substantially the same in the regions between nanoribbons 104a/104b along the second direction. The length of the gate structures may then be controllably altered via the process described herein by changing the width of the inner spacers at nanoribbons 104a/104b.

According to some embodiments, a dielectric fill 120 is present along the source/drain trench (e.g., extending along the second direction) between source or drain regions 108/109. Dielectric fill 120 may be present to isolate adjacent source or drain regions and may include any suitable dielectric material, such as silicon dioxide. In some embodiments, one or more gate cut structures may extend along the first direction between adjacent semiconductor devices to separate the gates of the adjacent semiconductor devices. Such gate cut structures can further extend across any number of gate trenches and source/drain trenches to separate any number of devices. In some examples, the gate cut structures are wide enough in the second direction to extend substantially the entire distance between adjacent source or drain regions.

### Fabrication Methodology

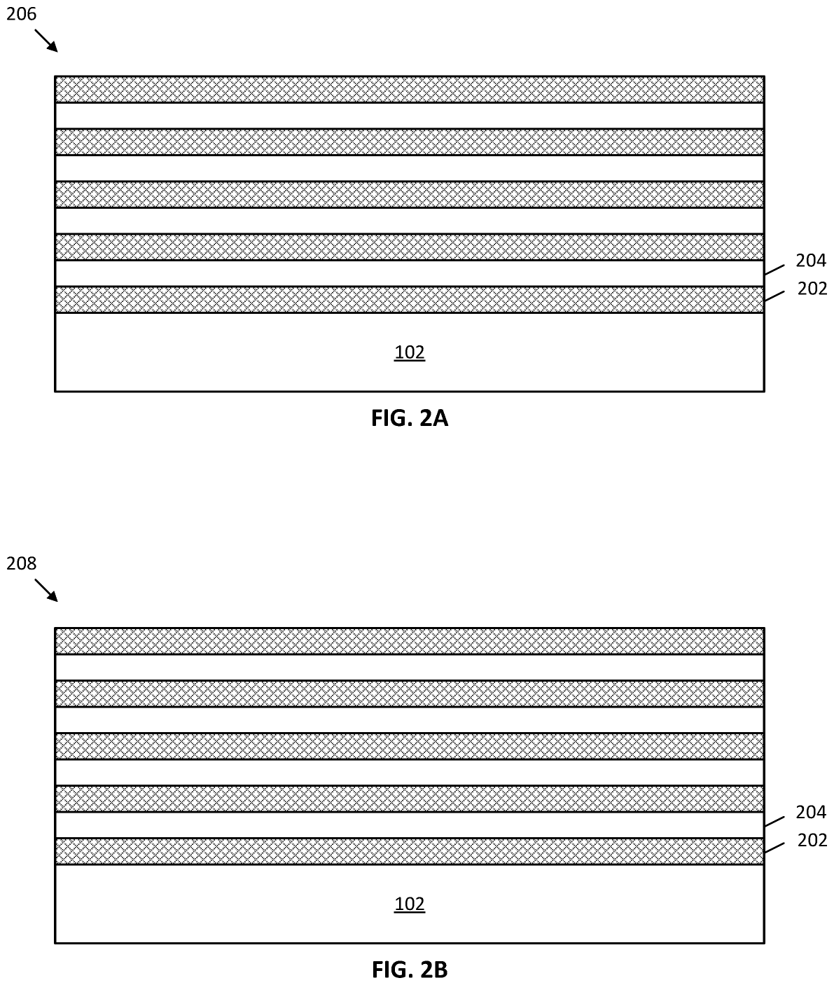

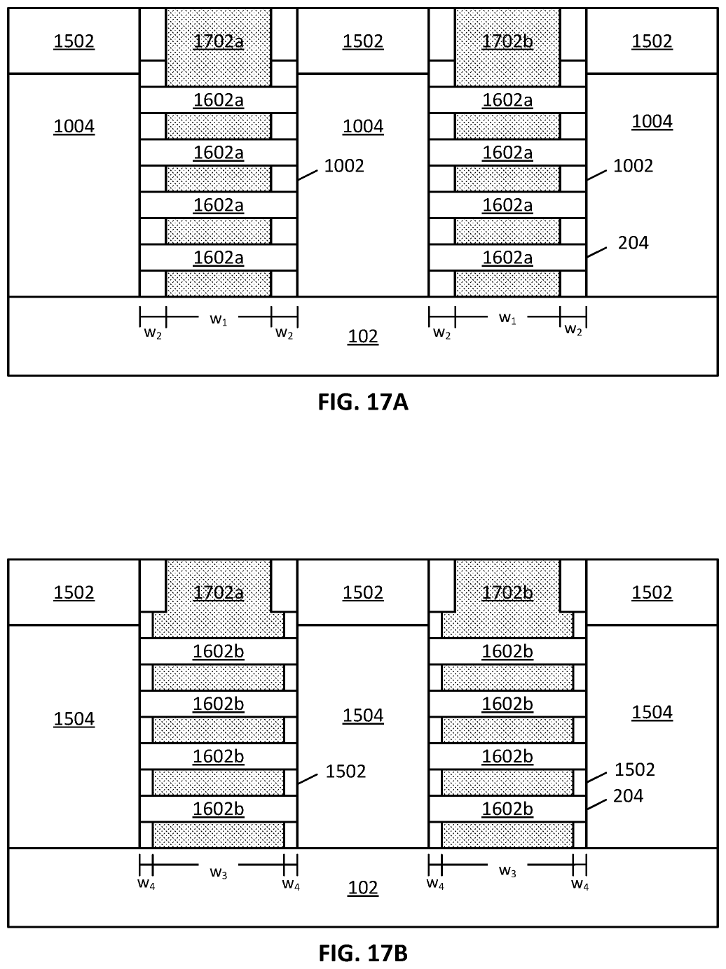

FIGS. 2A-17A and 2B-17B include cross-sectional views that collectively illustrate an example process for forming an integrated circuit having semiconductor devices with different gate lengths, in accordance with an embodiment of the present disclosure. FIGS. 2A-17A represent a similar cross-sectional view taken across a first set of semiconductor devices like those illustrated in FIG. 1A, while FIGS. 2B-17B represent a similar cross-sectional view taken across a second set of semiconductor devices like those illustrated in FIG. 1B. Each set of figures sharing the same letter shows an example structure that results from the process flow up to that point in time, so the depicted structure evolves as the process flow continues, culminating in the structures shown in FIGS. 17A and 17B, which is similar to the structures shown in FIGS. 1A and 1B, respectively. Such structures may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. The process described herein in FIGS. 2-17 may be repeated any number of times for any number of semiconductor devices to form devices with differing gate lengths.

FIGS. 2A and 2B each illustrates a cross-sectional view taken through substrate 102 having a series of material layers formed over the substrate, according to an embodiment of the present disclosure. Alternating material layers may be deposited over substrate 102 including sacrificial layers 202 alternating with semiconductor layers 204. The alternating layers are used to form GAA transistor structures. Any number of alternating sacrificial layers 202 and semiconductor layers 204 may be deposited over substrate 102. It should be noted that the cross-sections illustrated in FIGS. 2A and 2B are taken along the length of a first fin 206 parallel to a second fin 208 that are each formed from the multiple layers and extending up above the surface of substrate 102.

According to some embodiments, semiconductor layers 204 have a different material composition than sacrificial layers 202. In some embodiments, semiconductor layers 204 are silicon germanium (SiGe) while sacrificial layers 202 include a semiconductor material suitable for use as a nanoribbon such as silicon (Si), SiGe, germanium, or III-V materials like indium phosphide (InP) or gallium arsenide (GaAs). In examples where SiGe is used in each of semiconductor layers 204 and in sacrificial layers 202, the germanium concentration is different between semiconductor layers 204 and sacrificial layers 202. For example, semiconductor layers 204 may include a higher germanium content compared to sacrificial layers 202. In some examples, sacrificial layers 202 may be doped with either n-type dopants (to produce a p-channel transistor) or p-type dopants (to produce an n-channel transistor). Note that a sacrificial layer 202 is provided as both the first and last layer of the layer stack on substrate 102.

While dimensions can vary from one example embodiment to the next, the thickness of each semiconductor layer 204 may be between about 5 nm and about 20 nm. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any known material deposition technique, such as chemical vapor deposition (CVD), plasma-enhanced chemical vapor deposition (PECVD), physical vapor deposition (PVD), or atomic layer deposition (ALD), or epitaxial growth.

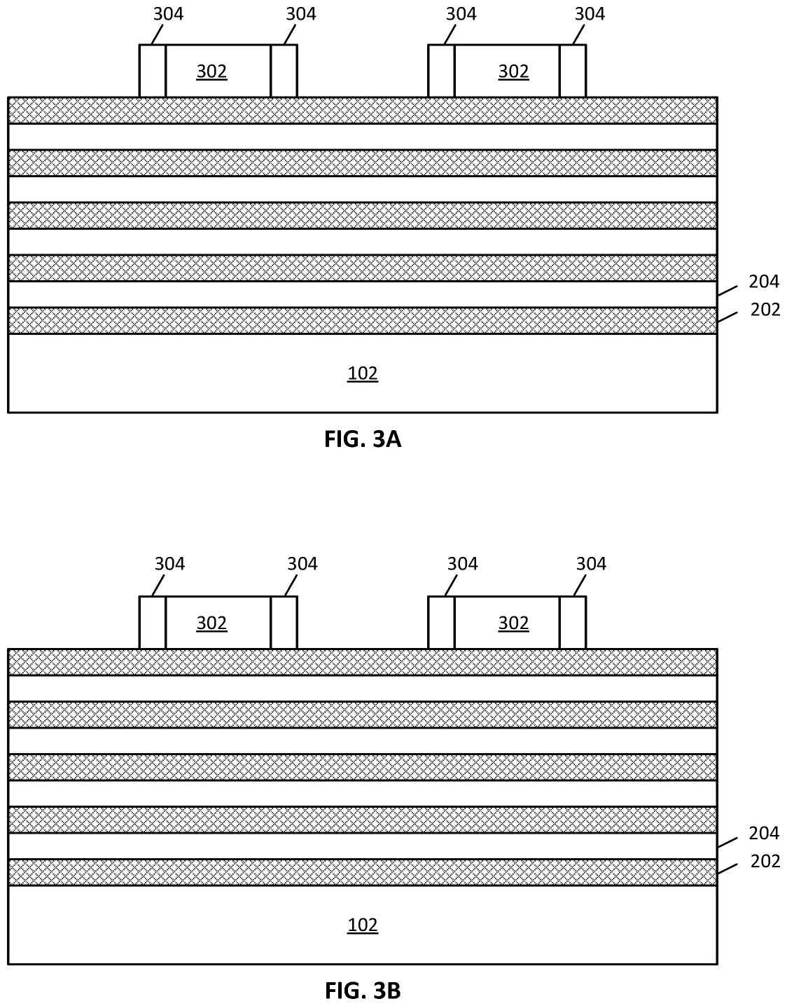

FIGS. 3A and 3B depict the cross-section views of the structure shown in FIGS. 2A and 2B, respectively, following the formation of sacrificial gate structures 302 and spacer structures 304 over the alternating layer structure of the fins, according to an embodiment. Sacrificial gate structures 302 may run in an orthogonal direction (e.g., along a second direction) to the length of the fins and may include any material that can be safely removed later in the process without etching or otherwise damaging any portions of the fins or of spacer structures 304. In some embodiments, sacrificial gate structures 302 include polysilicon. Spacer structures 304 may be formed using an etch-back process where spacer material is deposited everywhere and then anisotropically etched to leave the material only on sidewalls of structures including sacrificial gate structures 302. Spacer structures 304 may include a dielectric material, such as silicon nitride, silicon oxy-nitride, or any formulation of those layers incorporating carbon or boron dopants. Sacrificial gate structures 302 together with spacer structures 304 define portions of the fin that will be used to form first and second semiconductor devices, as discussed further herein. Note that the pitch and width across the first direction of sacrificial gate structures 302 is substantially the same across the fins illustrated in both FIGS. 3A and 3B, according to some embodiments.

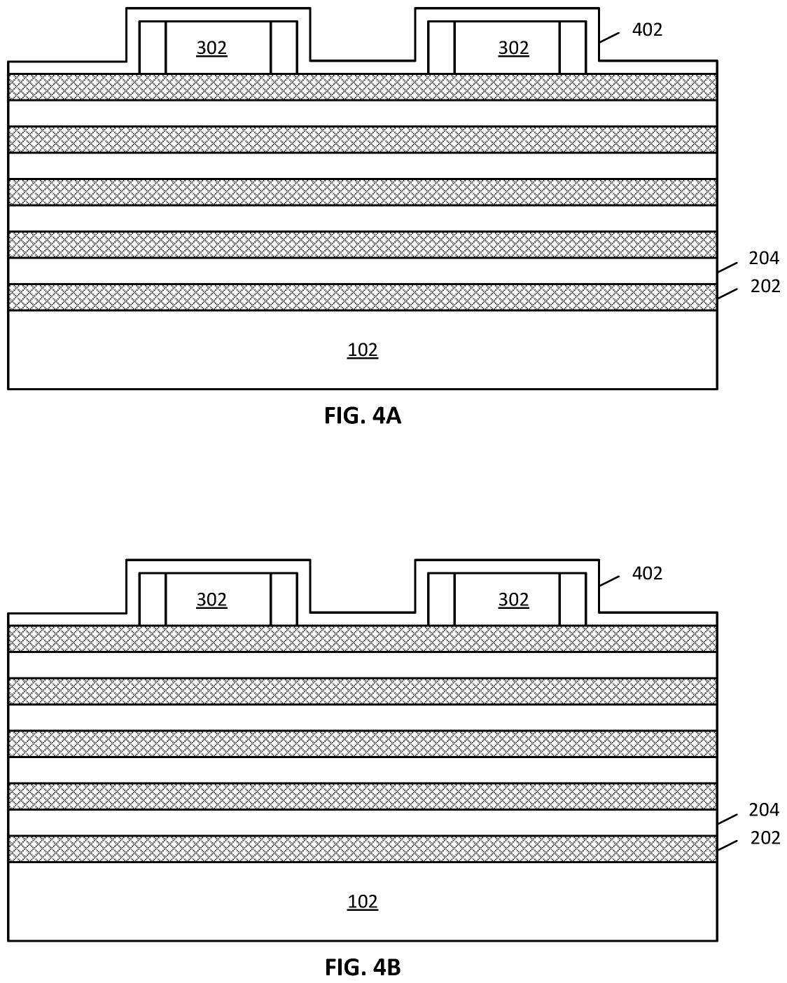

FIGS. 4A and 4B depict cross-section views of the structures shown in FIGS. 3A and 3B following the formation of a dielectric structure 402 over the fins and sacrificial gate structures 302, according to some embodiments. Dielectric structure 402 may represent any number of dielectric layers and may include any suitable dielectric materials to protect the underlying materials from subsequent processing operations. In some examples, dielectric structure 402 includes one or more layers of silicon oxycarbonitride, silicon oxycarbide, and/or silicon nitride.

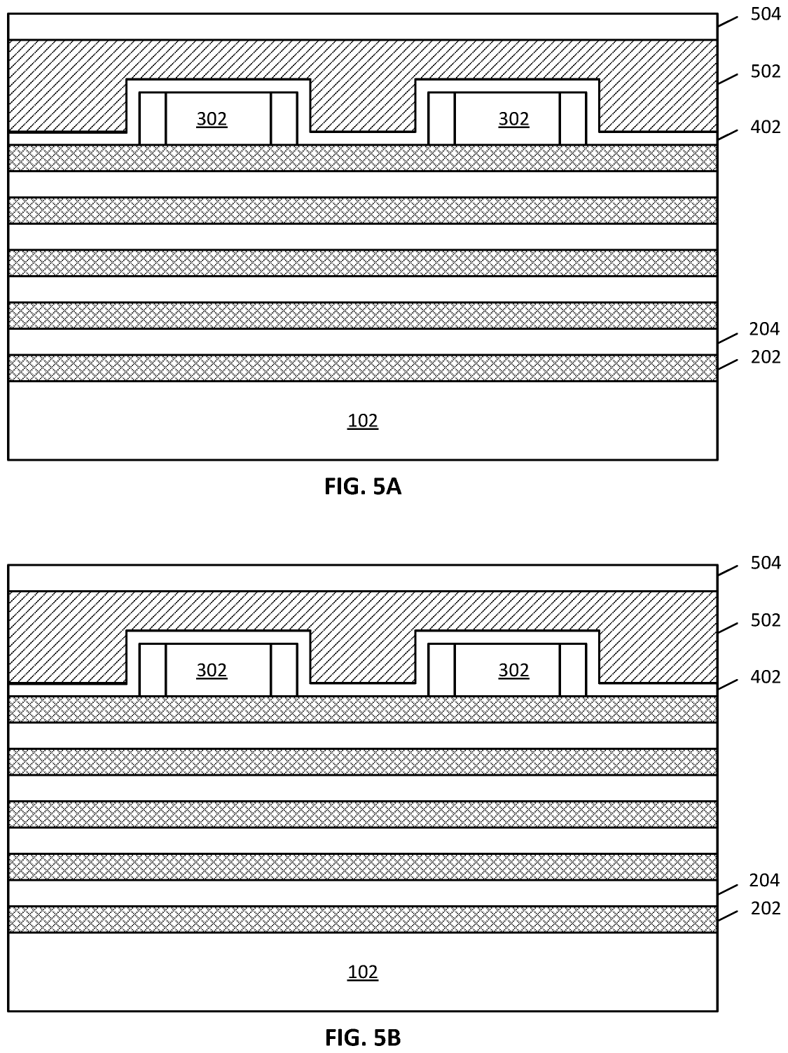

FIGS. 5A and 5B depict cross-section views of the structures shown in FIGS. 4A and 4B following the formation of additional masking layers over dielectric structure 402, according to some embodiments. For example, a first masking structure 502 may be formed over dielectric structure 402 and may include any suitable photoresist or carbon hard mask (CHM) material. A second masking structure 504 may be formed over first masking structure 502 and may include a hard mask material with a high etch selectivity, such as titanium nitride. Other suitable materials may be used for each of first masking structure 502 and second masking structure 504, as will be appreciated.

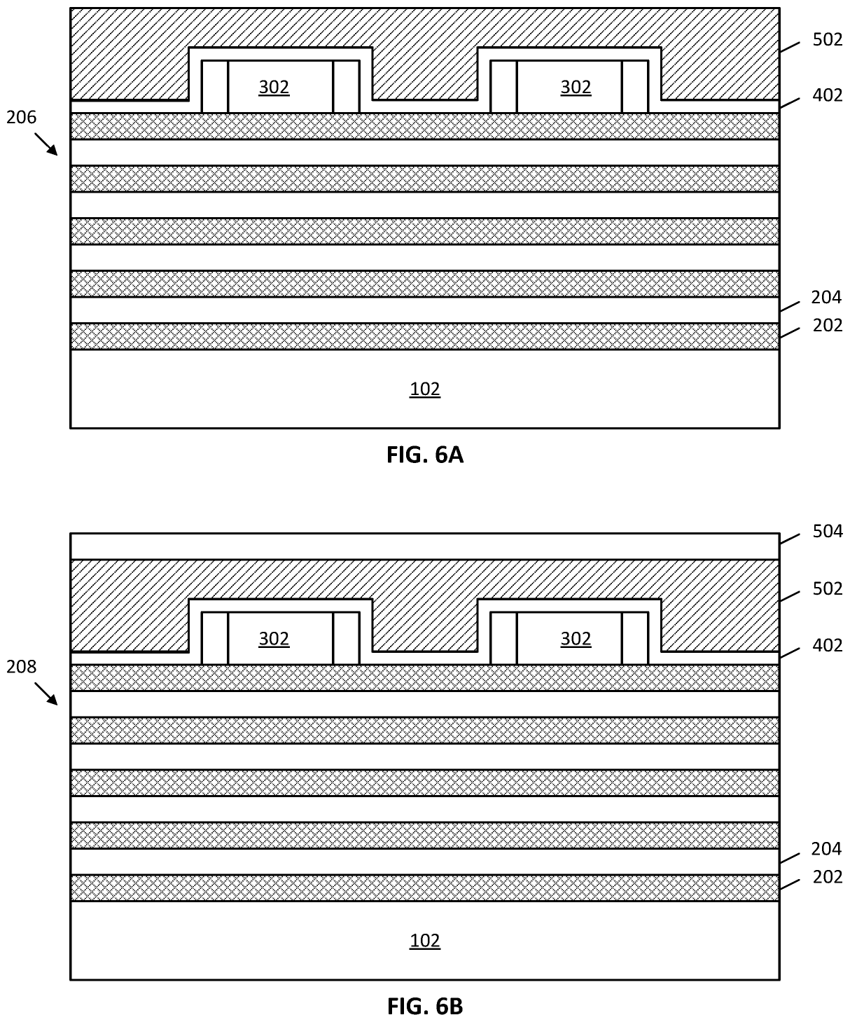

FIGS. 6A and 6B depict cross-section views of the structures shown in FIGS. 5A and 5B following the selective removal of second masking structure 504 over first fin 206 of FIG. 6A, according to some embodiments. Second masking structure 504 remains over second fin 208 of FIG. 6B. Any suitable photolithography process may be carried out to selectively pattern second masking structure 504.

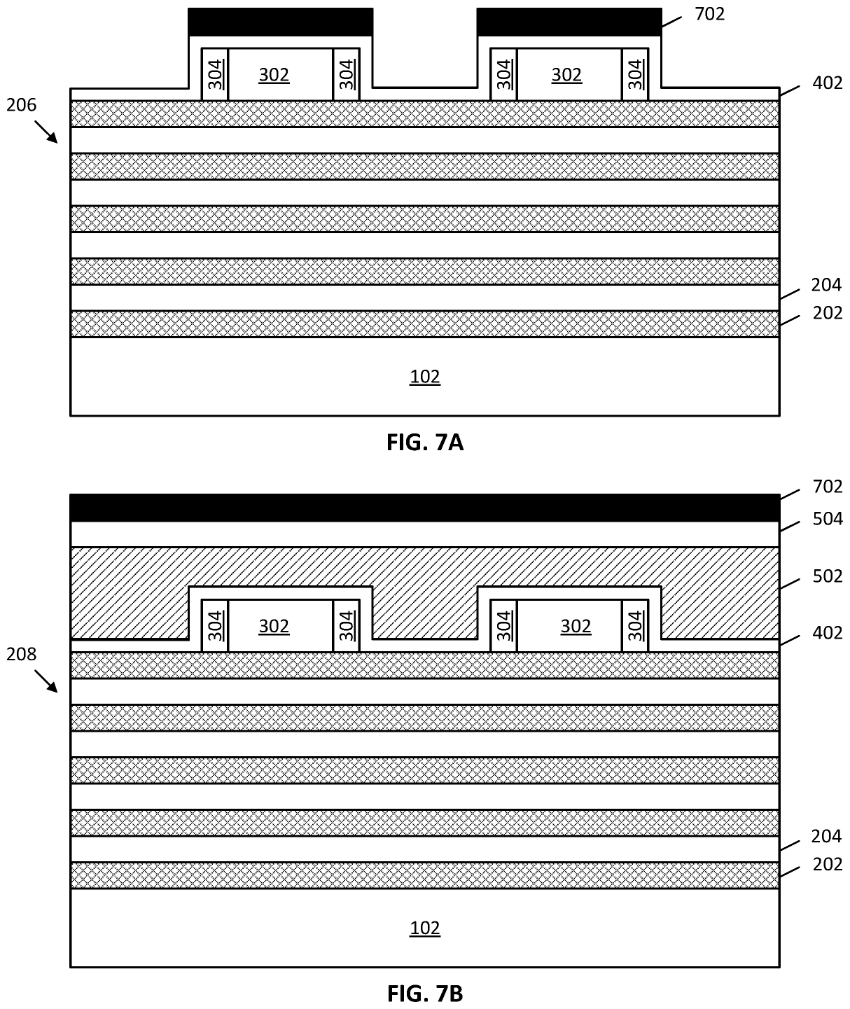

FIGS. 7A and 7B depict cross-section views of the structure shown in FIGS. 6A and 6B, respectively, following the removal of the exposed first masking structure 502 above first fin 206 in FIG. 7A, and the subsequent formation of helmet structure 702, according to some embodiments. Exposed portions of first masking structure 502 above first fin 206 may be removed using any suitable isotropic etching process. Helmet structure 702 may be deposited using an angled or any other directed process such that helmet structure 702 forms primarily along the top of sacrificial gate structures 302 and spacer structures 304. Specifically, helmet structure 702 is formed such that it does not deposit (or deposits very little) along the top of first fin 206 between sacrificial gate structures 302 and spacer structures 304. Some portions of helmet structure 702 may form along sidewalls of spacer structures 304. Helmet structure 702 may include any suitable hard mask dielectric material, such as silicon nitride.

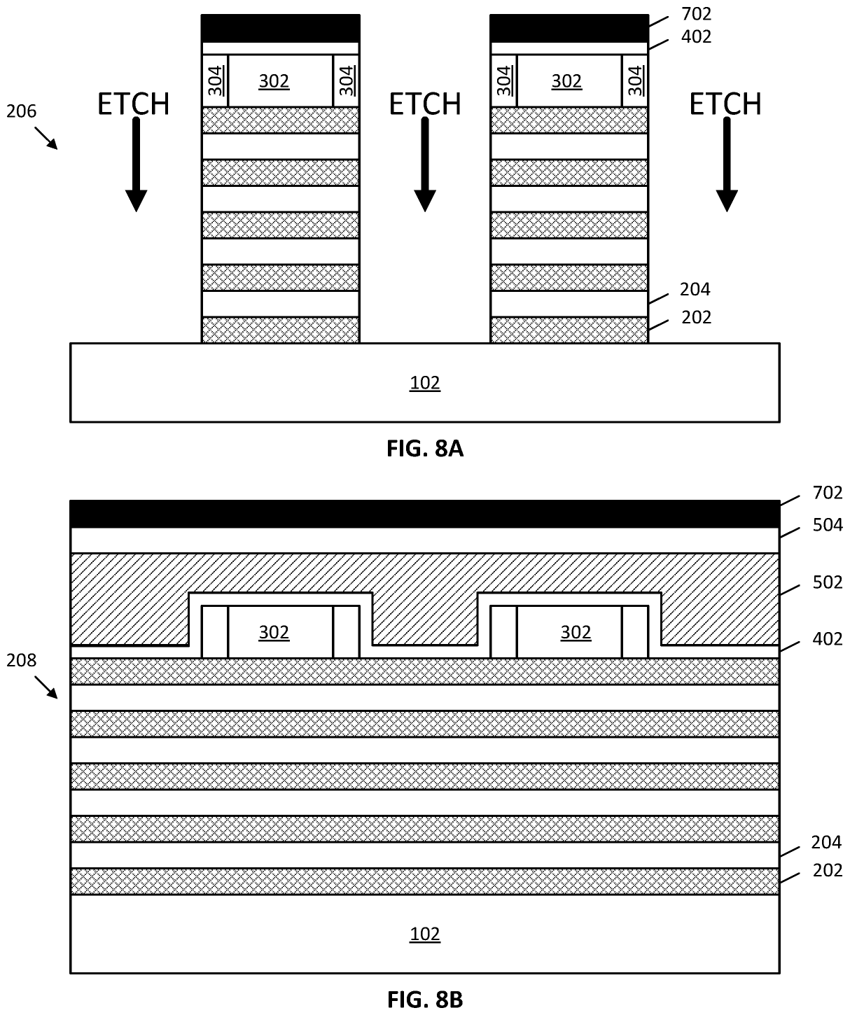

FIGS. 8A and 8B depict cross-section views of the structure shown in FIGS. 7A and 7B, respectively, following the removal of the exposed portions of first fin 206 not under helmet structure 702, according to an embodiment of the present disclosure. According to some embodiments, the various alternating material layers are etched together using an anisotropic RIE process. In some embodiments, some undercutting occurs along the edges of the resulting fin structures beneath spacer structures 304 such that the length of a given fin structure is not exactly the same as a sum of the widths of spacer structures 304 and a width of sacrificial gate structure 302. The RIE process may also etch into substrate 102 thus recessing portions of substrate 102 on either side of any of the fin structures.

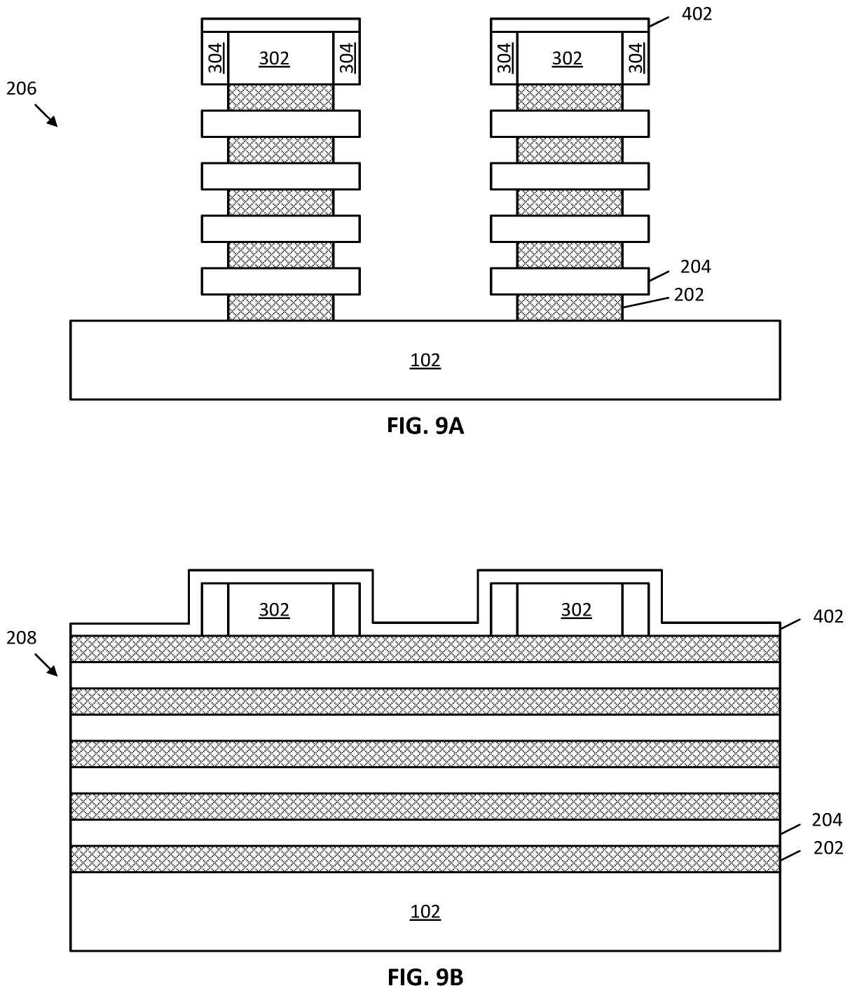

FIGS. 9A and 9B depict cross-section views of the structure shown in FIGS. 8A and 8B, respectively, following the removal of portions of sacrificial layers 202, according to an embodiment of the present disclosure. Additionally, the various masking layers and helmet structure 702 are also removed using any number of isotropic etching or ashing processes. A selective and timed isotropic etching process may be used to recess the exposed ends of each sacrificial layers 202 of first fin 206. The etch is selective to semiconductor layers 204 and gate spacers 304, so as to largely remove only sacrificial layers 202. Note that second fin 208 is still protected by dielectric structure 402 and thus no etching occurs of the sacrificial layers 202 from second fin 208. The amount of recessing of sacrificial layers 202 dictates the width of the inner spacer structures that will be formed for the devices of first fin 206. To this end, the dwell time of the recess etch can be set to provide a desired recess depth. In the illustrated example, sacrificial layers 202 of first fin 206 have been recessed to a lateral depth that is substantially similar to a width of spacer structures 304 along the first direction. Note the example structure here is described in terms of nanoribbons and a gate-all-around architecture. However, the structure could also be described in terms of nanosheets and a forksheet architecture. In such a case, the nanosheets would extend out from the page from a dielectric wall, with FIG. 9A showing one type of devices (e.g., n-type FETs or logic devices) on one side of the dielectric wall and FIG. 9B showing another type of devices (e.g., p-type FETs or memory devices) on the other side of the dielectric wall. The techniques described herein can be applied to such a forksheet configuration to achieve a similar benefit, according to some example embodiments.

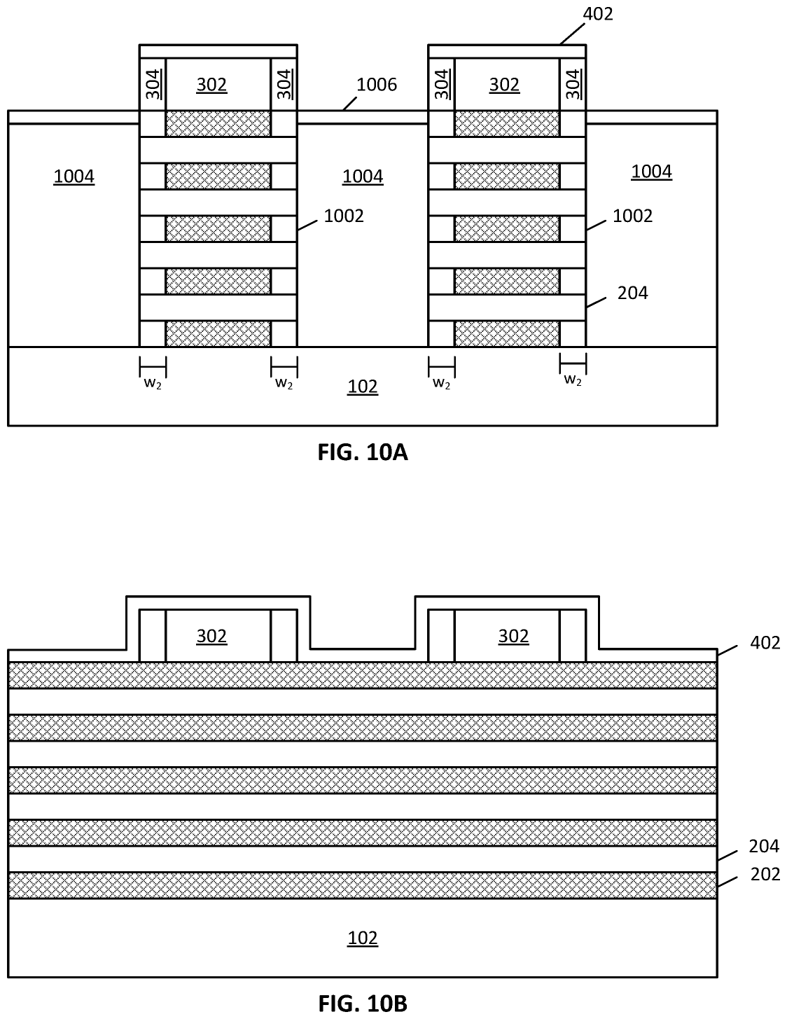

FIGS. 10A and 10B depict cross-section views of the structure shown in FIGS. 9A and 9B, respectively, following the formation of first inner spacers 1002 and first source or drain regions 1004, according to an embodiment of the present disclosure. First inner spacers 1002 may have a material composition that is similar to or the exact same as spacer structures 304, but may also be compositionally and/or structurally different, such as in the case of example configurations where first inner spacers 1002 include one or more elements and/or layers not included in spacer structures 304, or vice-versa. Accordingly, first inner spacers 1002 may be any suitable dielectric material that exhibits high etch selectively to semiconductor materials such as silicon and/or silicon germanium (or other semiconductor channel materials). First inner spacers 1002 may be conformally deposited over the sides of the fin structure using a deposition process like CVD or ALD and then etched back using an isotropic etching process to expose the ends of semiconductor layers 204.

Based on the recessed depth of sacrificial layers 202, first inner spacers 1002 have a lateral width w₂. According to some embodiments, width w₂ is between about 5 nm and about 7 nm. In some such examples, spacer structures 304 have a similar width (e.g., w₂+/−5 angstroms).

First source or drain regions 1004 may be epitaxially grown from the exposed ends of semiconductor layers 204, according to some embodiments. As noted above, any of first source or drain regions 1004 can act as either a source or drain depending on the application. Any semiconductor materials suitable for first source or drain regions 1004 can be used (e.g., group IV and group III-V semiconductor materials). First source or drain regions 1004 may include multiple layers such as liners and capping layers to improve contact resistance. In any such cases, the composition and doping of first source or drain regions 1004 may be the same, such that first source or drain regions 1004 are all n-type regions or all p-type regions. Any number of source or drain configurations and materials can be used. In some embodiments, a cap layer 1006 may be formed over first source or drain regions 1004 for protection. Cap layer 1006 may be any suitable dielectric material, such as silicon nitride or silicon oxycarbonitride.

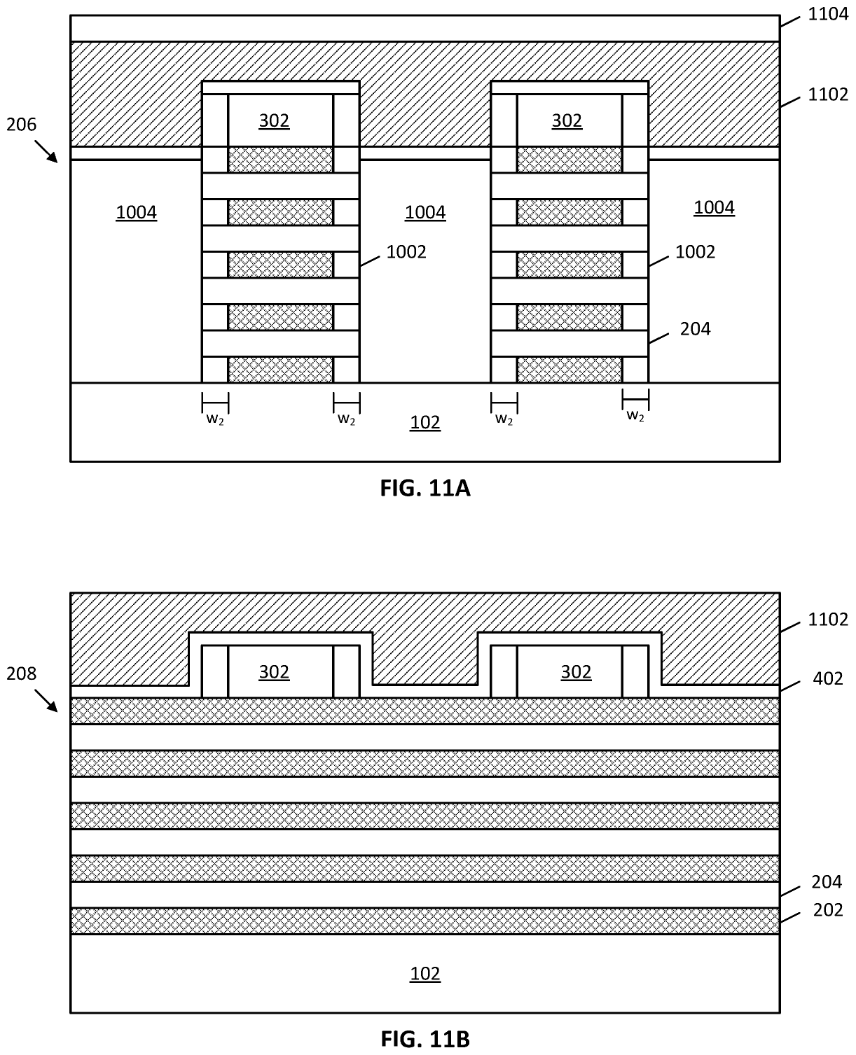

Once the formation of first source or drain regions 1004 from first fin 206 is complete, the processing of second fin 208 can occur, according to some embodiments. FIGS. 11A and 11B depict cross-section views of the structure shown in FIGS. 10A and 10B, respectively, following the formation of a first masking structure 1102 and a second masking structure 1104. First masking structure 1102 may be substantially similar to first masking structure 502 and second masking structure 1104 may be substantially similar to second masking structure 504. Additionally, second masking structure 1104 may be patterned to expose first masking structure 1102 over second fin 208 while remaining over first fin 206.

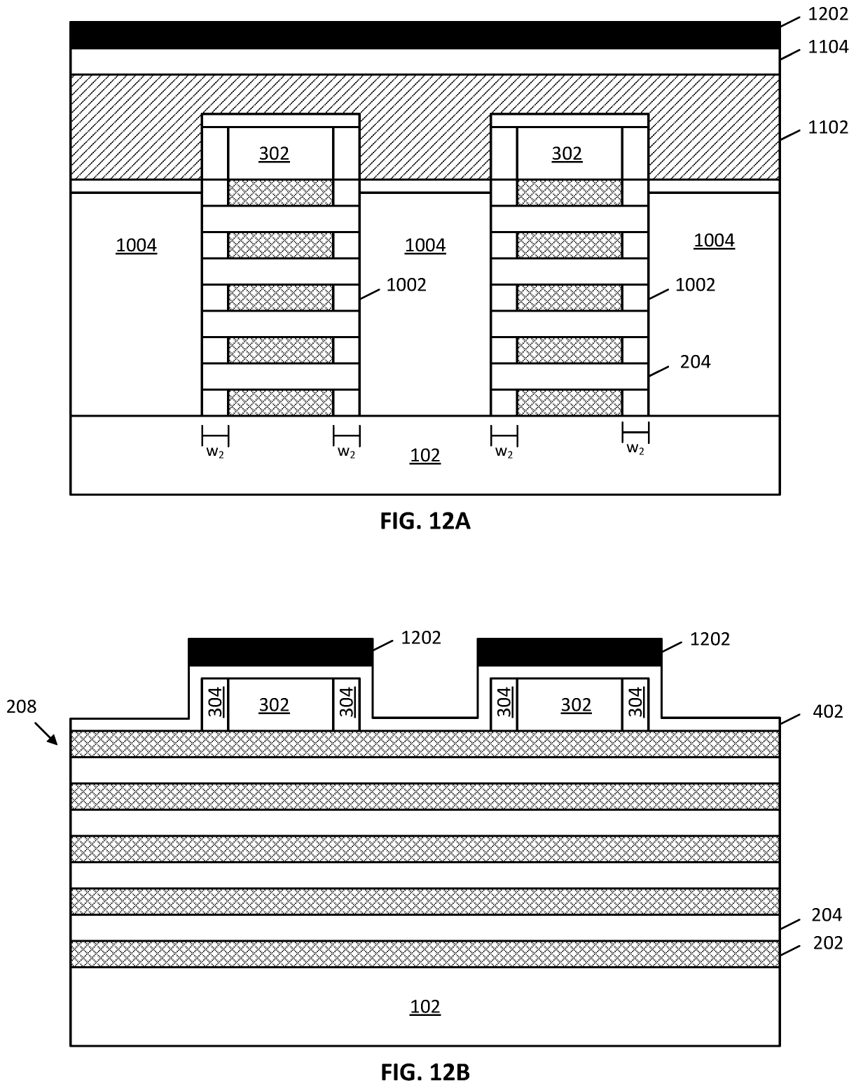

FIGS. 12A and 12B depict cross-section views of the structure shown in FIGS. 11A and 11B, respectively, following the formation of helmet structure 1202, according to some embodiments. Helmet structure 1202 may be deposited using an angled or any other directed process such that helmet structure 1202 forms primarily along the top of sacrificial gate structures 302 and spacer structures 304. Specifically, helmet structure 1202 is formed such that it does not deposit (or deposits very little) along the top of second fin 208 between sacrificial gate structures 302 and spacer structures 304. Some portions of helmet structure 1202 may form along sidewalls of spacer structures 304. Helmet structure 1202 may include any suitable hard mask dielectric material, such as silicon nitride.

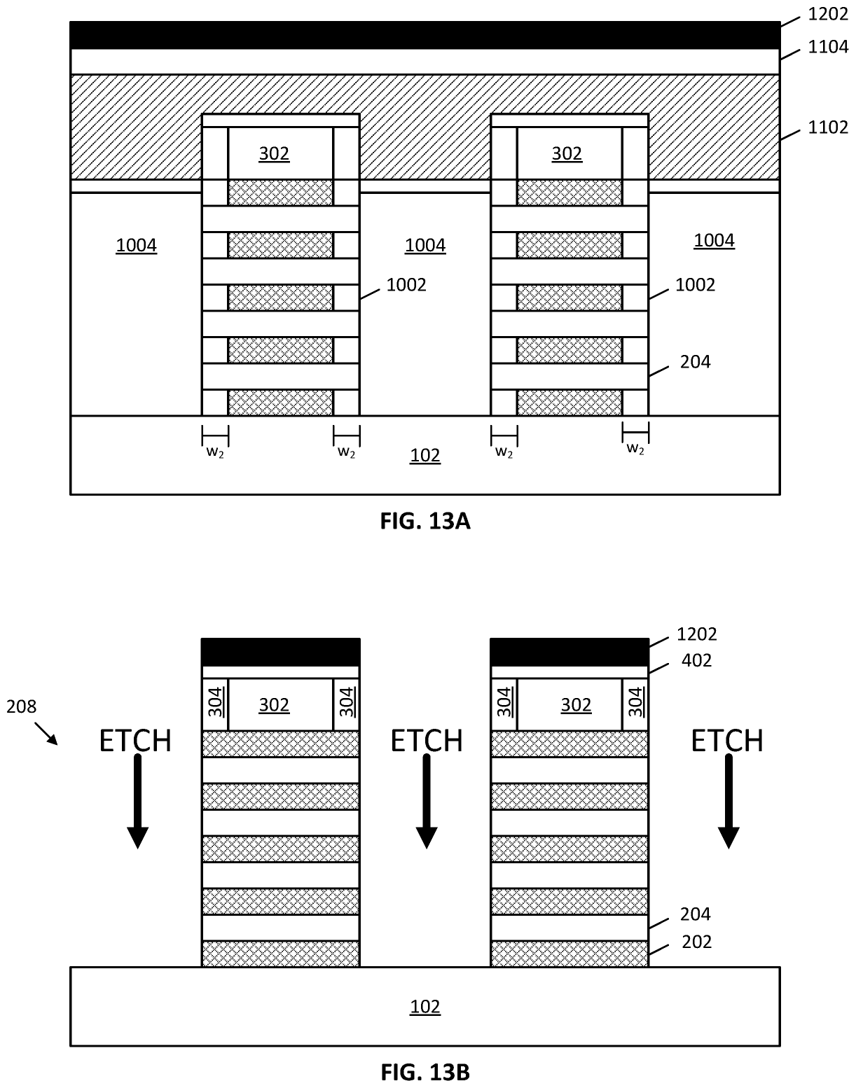

FIGS. 13A and 13B depict cross-section views of the structure shown in FIGS. 12A and 12B, respectively, following the removal of the exposed portions of second fin 208 not under helmet structure 1202, according to an embodiment of the present disclosure. According to some embodiments, the various alternating material layers are etched together using an anisotropic RIE process. In some embodiments, some undercutting occurs along the edges of the resulting fin structures beneath spacer structures 304 such that the length of a given fin structure is not exactly the same as a sum of the widths of spacer structures 304 and a width of sacrificial gate structure 302. The RIE process may also etch into substrate 102 thus recessing portions of substrate 102 on either side of any of the fin structures.

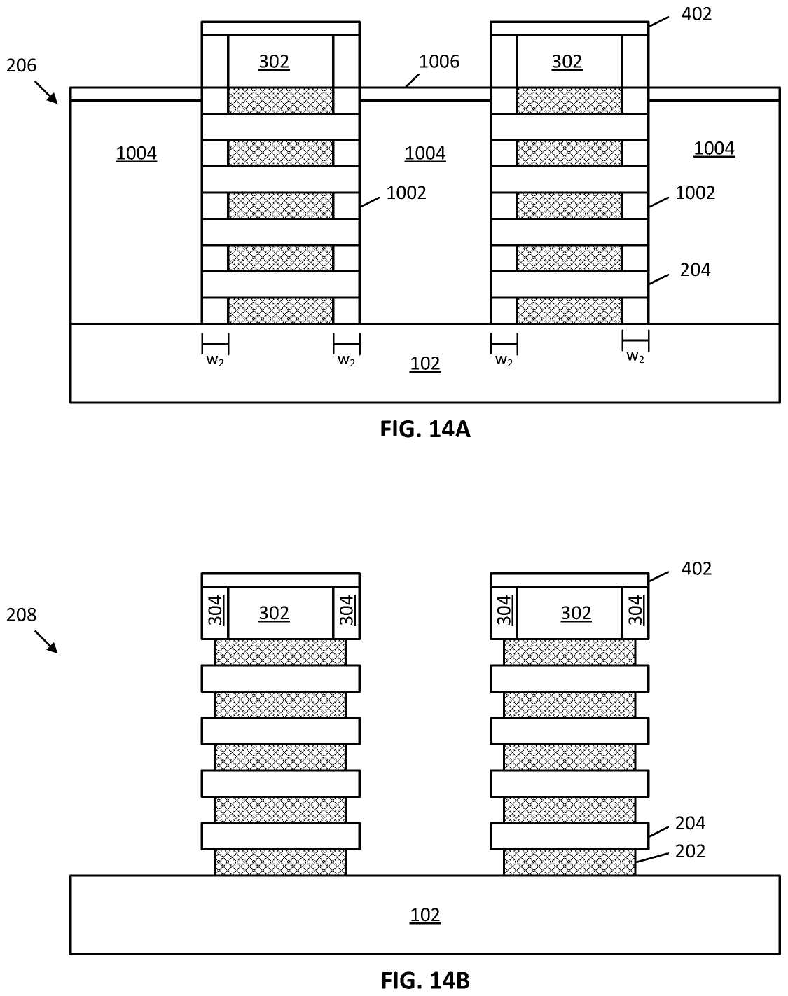

FIGS. 14A and 14B depict cross-section views of the structure shown in FIGS. 13A and 13B, respectively, following the removal of portions of sacrificial layers 202, according to an embodiment of the present disclosure. Additionally, the various masking layers and helmet structure 1202 are also removed using any number of isotropic etching or ashing processes. A selective and timed isotropic etching process may be used to recess the exposed ends of each sacrificial layers 202 of second fin 208. The etch is selective to semiconductor layers 204 and gate spacers 304, so as to largely remove only sacrificial layers 202. Note that first fin 206 is protected by both dielectric structure 402 and cap layer 1006. The amount of recessing of sacrificial layers 202 dictates the width of the inner spacer structures that will be formed for the devices of second fin 208. To this end, the dwell time of the recess etch can be set to provide a desired recess depth. In the illustrated example, sacrificial layers 202 of second fin 208 have been recessed to a lateral depth that is less than a width of spacer structures 304 along the first direction. The previous above description with respect to forksheet devices is equally applicable here.

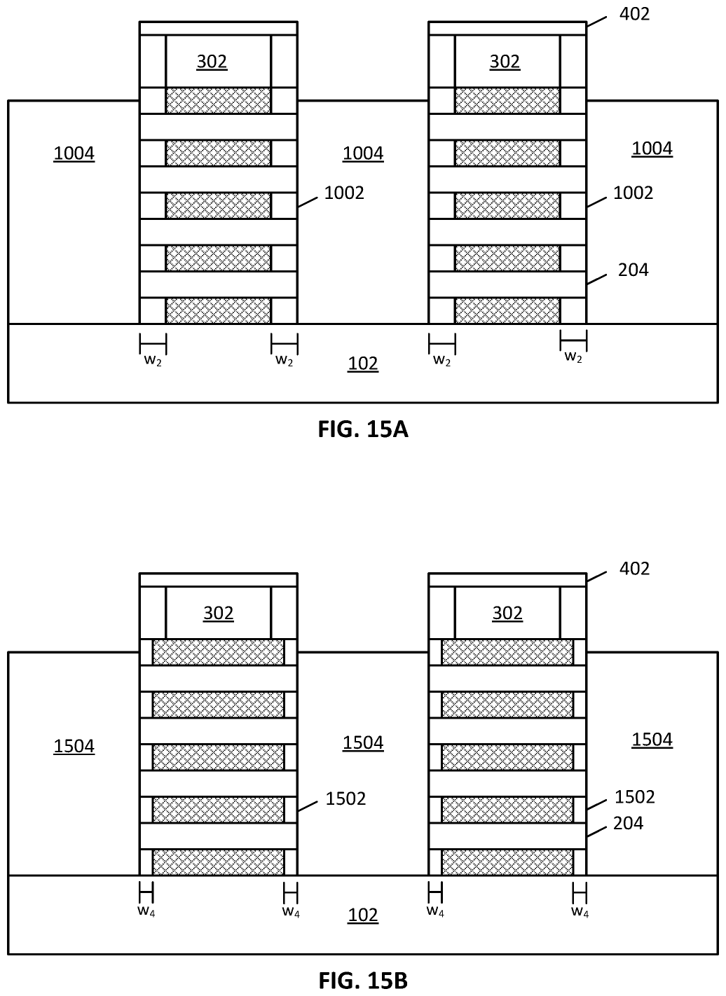

FIGS. 15A and 15B depict cross-section views of the structure shown in FIGS. 14A and 14B, respectively, following the formation of second inner spacers 1502 and second source or drain regions 1504, according to an embodiment of the present disclosure. Second inner spacers 1502 may have a material composition that is similar to or the exact same as spacer structures 304 and/or first inner spacers 1002. Accordingly, second inner spacers 1502 may be any suitable dielectric material that exhibits high etch selectively to semiconductor materials such as silicon and/or silicon germanium. Second inner spacers 1502 may be conformally deposited over the sides of the fin structure using a deposition process like CVD or ALD and then etched back using an isotropic etching process to expose the ends of semiconductor layers 204. The previous description with respect to first inner spacers 1002 being compositionally and/or structurally different from spacer structures 304 is equally applicable to second inner spacers 1502. According to some embodiments, cap layer 1006 may be removed from over first source or drain regions 1004 using any suitable etching process.

Based on the recessed depth of sacrificial layers 202, second inner spacers 1502 have a lateral width w₄. According to some embodiments, width w₄ is between about 3 nm and about 5 nm. More generally, width w₄ may be about 2 nm or more less than width w₂, so as to allow for diverse gate lengths.

Second source or drain regions 1504 may be epitaxially grown from the exposed ends of semiconductor layers 204, according to some embodiments. As noted above, any of second source or drain regions 1504 can act as either a source or drain depending on the application. Any semiconductor materials suitable for second source or drain regions 1504 can be used (e.g., group IV and group III-V semiconductor materials). Second source or drain regions 1504 may include multiple layers such as liners and capping layers to improve contact resistance. In any such cases, the composition and doping of second source or drain regions 1504 may be the same, such that second source or drain regions 1504 are all n-type regions or all p-type regions. In some examples, first source or drain regions 1004 may be n-type regions while second source or drain regions 1504 may be p-type regions. Any number of source or drain configurations and materials can be used.

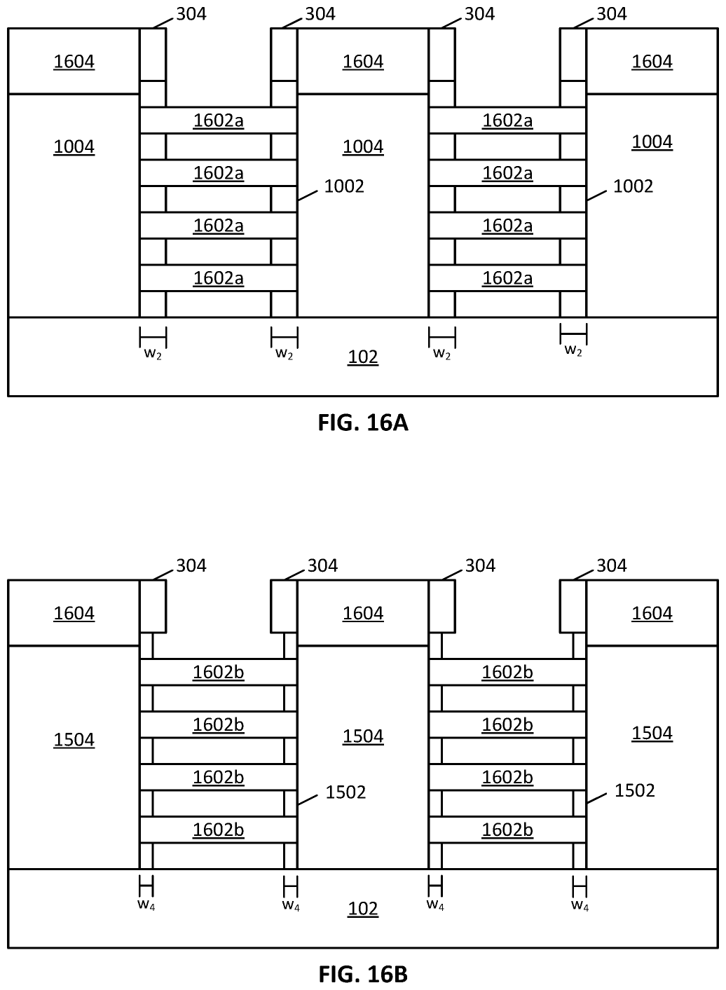

FIGS. 16A and 16B depict cross-section views of the structure shown in FIGS. 15A and 15B, respectively, following the removal of sacrificial gate structures 302 and sacrificial layers 202, according to some embodiments. In examples where any gate masking layers are still present, they would be removed at this time. Once sacrificial gate structures 302 are removed, the fins extending between first and second inner spacers 1002 and 1502 are exposed.

In the example where the fins include alternating semiconductor layers, sacrificial layers 202 are selectively removed to leave behind nanoribbons 1602a that extend between first source or drain regions 1004 along the first direction and nanoribbons 1602b that extend between second source or drain regions 1504 along the first direction. Each vertical set of nanoribbons 1602a/1602b represents the semiconductor region (or channel region) of a different semiconductor device. Recall from above that nanoribbons 1602a/1602b may also be nanowires or nanosheets. Sacrificial gate structures 302 and sacrificial layers 202 may be removed using the same isotropic etching process or different isotropic etching processes.

According to some embodiments, any remaining volume within the source/drain trenches may be filled with a dielectric fill 1604. Accordingly, dielectric fill 1604 may be formed directly above any number of source or drain regions 1004/1504. A top surface of dielectric fill 1604 may be polished using, for example, chemical mechanical polishing (CMP) so that it is substantially coplanar with a top surface of the adjacent spacer structures 304.

FIGS. 17A and 17B depict cross-section views of the structure shown in FIGS. 16A and 16B, respectively, following the formation of gate structures 1702a and 1702b, according to some embodiments. Each of the gate structures 1702a/1702b includes a gate dielectric and a gate electrode on the gate dielectric. The gate dielectric may be first formed around nanoribbons 1602a/1602b prior to the formation of the gate electrode, which may include one or more conductive layers. The gate dielectric may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric includes a layer of hafnium oxide with a thickness between about 1 nm and about 5 nm. In some embodiments, the gate dielectric may include one or more silicates (e.g., titanium silicate, tungsten silicate, niobium silicate, and silicates of other transition metals). In some cases, the gate dielectric includes a first layer on nanoribbons 1602a/1602b, and a second layer on the first layer. The first layer can be, for instance, an oxide of the semiconductor material of nanoribbons 1602a/1602b (e.g., silicon dioxide) and the second layer can be a high-k dielectric material (e.g., hafnium oxide). In some embodiments, the gate dielectric may also be deposited and left on the gate-side facing surfaces of inner spacers 1002 and 1502, and on gate-side facing surfaces of gate spacers 304, and on the bottom of the gate trench on substrate 102. The gate dielectric may be, for instance, conformally deposited using CVD or ALD.

The one or more conductive layers that make up the gate electrode may be deposited using electroplating, electroless plating, CVD, PECVD, ALD, or PVD, to name a few examples. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

According to some embodiments, the gate lengths are different around nanoribbons 1602a compared to nanoribbons 1602b due to the difference in the widths of first inner spacers 1002 and second inner spacers 1502. Accordingly, the gate length w₃ of the gate structures around nanoribbons 1602b may be at least 3 nm, at least 4 nm, or at least 5 nm greater than the gate length w₁ of the gate structures around nanoribbons 1602a, according to a few example embodiments. According to some such example embodiments, the gate length w₁ across nanoribbons 1602a may be between about 12 nm and about 18 nm and the gate length w₃ across nanoribbons 1602b may be between about 16 nm and about 22 nm.

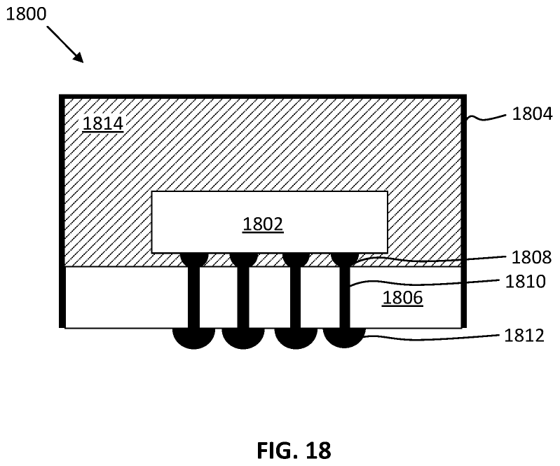

FIG. 18 illustrates an example embodiment of a chip package 1800, in accordance with an embodiment of the present disclosure. As can be seen, chip package 1800 includes one or more dies 1802. One or more dies 1802 may include at least one integrated circuit having semiconductor devices, such as any of the semiconductor devices disclosed herein. One or more dies 1802 may include any other circuitry used to interface with other devices formed on the dies, or other devices connected to chip package 1800, in some example configurations.

As can be further seen, chip package 1800 includes a housing 1804 that is bonded to a package substrate 1806. The housing 1804 may be any standard or proprietary housing, and may provide, for example, electromagnetic shielding and environmental protection for the components of chip package 1800. The one or more dies 1802 may be conductively coupled to a package substrate 1806 using connections 1808, which may be implemented with any number of standard or proprietary connection mechanisms, such as solder bumps, ball grid array (BGA), pins, or wire bonds, to name a few examples. Package substrate 1806 may be any standard or proprietary package substrate, but in some cases includes a dielectric material having conductive pathways (e.g., including conductive vias and lines) extending through the dielectric material between the faces of package substrate 1806, or between different locations on each face. In some embodiments, package substrate 1806 may have a thickness less than 1 millimeter (e.g., between 0.1 millimeters and 0.5 millimeters), although any number of package geometries can be used. Additional conductive contacts 1812 may be disposed at an opposite face of package substrate 1806 for conductively contacting, for instance, a printed circuit board (PCB). One or more vias 1810 extend through a thickness of package substrate 1806 to provide conductive pathways between one or more of connections 1808 to one or more of contacts 1812. Vias 1810 are illustrated as single straight columns through package substrate 1806 for ease of illustration, although other configurations can be used (e.g., damascene, dual damascene, through-silicon via, or an interconnect structure that meanders through the thickness of substrate 1806 to contact one or more intermediate locations therein). In still other embodiments, vias 1810 are fabricated by multiple smaller stacked vias, or are staggered at different locations across package substrate 1806. In the illustrated embodiment, contacts 1812 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1812, to inhibit shorting.

In some embodiments, a mold material 1814 may be disposed around the one or more dies 1802 included within housing 1804 (e.g., between dies 1802 and package substrate 1806 as an underfill material, as well as between dies 1802 and housing 1804 as an overfill material). Although the dimensions and qualities of the mold material 1814 can vary from one embodiment to the next, in some embodiments, a thickness of mold material 1814 is less than 1 millimeter. Example materials that may be used for mold material 1814 include epoxy mold materials, as suitable. In some cases, the mold material 1814 is thermally conductive, in addition to being electrically insulating.

### Methodology

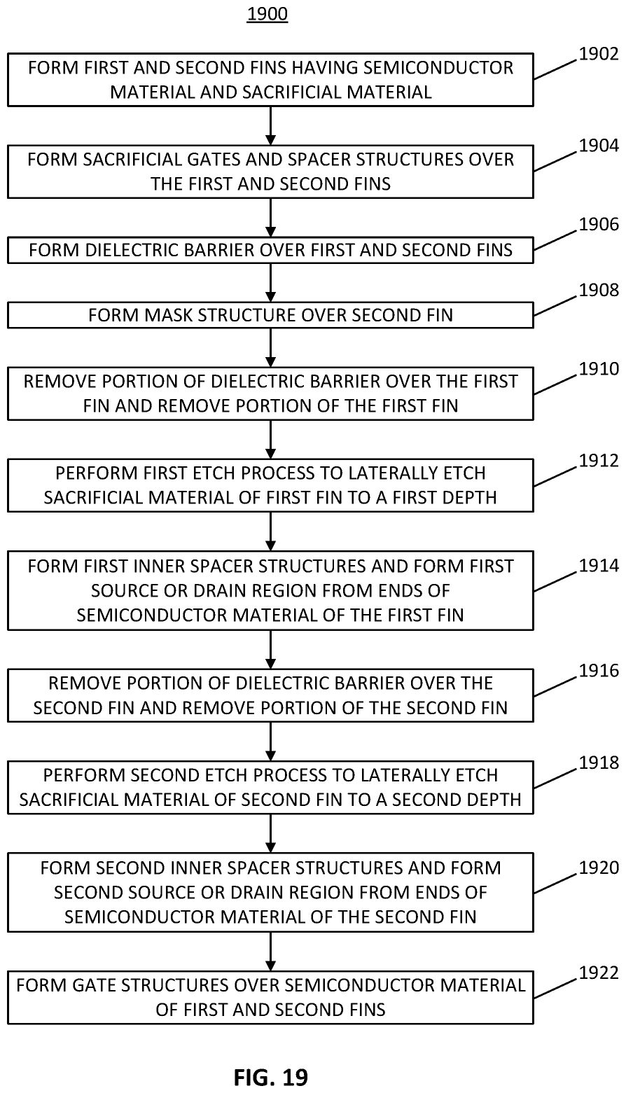

FIG. 19 is a flow chart of a method 1900 for forming at least a portion of an integrated circuit, according to an embodiment. Various operations of method 1900 may be illustrated in FIGS. 2A-17A and 2B-17B. However, the correlation of the various operations of method 1900 to the specific components illustrated in the aforementioned figures is not intended to imply any structural and/or use limitations. Rather, the aforementioned figures provide example embodiments of method 1900. Other operations may be performed before, during, or after any of the operations of method 1900. Some of the operations of method 1900 may be performed in a different order than the illustrated order.

Method 1900 begins with operation 1902 where first and second multilayer fins are formed having alternating semiconductor and sacrificial layers. The sacrificial layers may include SiGe while the semiconductor layers may be Si, SiGe, Ge, InP, or GaAs, to name a few examples. The thickness of each of the sacrificial and semiconductor layers may be between about 5 nm and about 20 nm or between about 5 nm and about 10 nm. Each of the sacrificial and semiconductor layers may be deposited using any known material deposition technique, such as CVD, PECVD, PVD, or ALD. The first and second fins may be defined by patterning sacrificial gates and spacer structures that extend orthogonally over the fins, then etching around the sacrificial gates and spacer structures via an anisotropic etching process, such as RIE. According to some embodiments, the multilayer fins include a sacrificial layer as a topmost layer and as a bottommost layer.

Method 1900 continues with operation 1904 where sacrificial gate and spacer structures are formed over the first and second fins, according to some embodiments. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may include any suitable dielectric material, such as silicon nitride or silicon oxynitride, or any number of different dielectric layers.

Method 1900 continues with operation 1906 where a dielectric barrier is formed over the first and second fins. The dielectric barrier may be blanked deposited across all structures of the integrated circuit. The dielectric barrier may include any number of dielectric layers and may include any suitable dielectric materials to protect the underlying materials from subsequent processing operations. In some examples, the dielectric barrier includes one or more layers of silicon oxycarbonitride and/or silicon oxycarbide.

Method 1900 continues with operation 1908 where a mask structure is formed over the second fin. According to some embodiments, the mask structure includes any number of masking layers and is patterned to expose the first fin while protecting the second fin. For example, the mask structure may include one or more CHM layers and/or one or more hard mask layers, such as titanium nitride.

Method 1900 continues with operation 1910 where the dielectric barrier is removed over the exposed first fin and portions of the first fin are removed from between the sacrificial gates and spacer structures. According to some embodiments, the various alternating material layers of the first fin are etched together using an anisotropic RIE process. The RIE process may also etch into the substrate thus recessing portions of the substrate on either side of any of the fin structures.

Method 1900 continues with operation 1912 where an isotropic and selective etching process is performed to laterally the etch the exposed sacrificial layers of the first fin to a first lateral depth. Note that the second fin is still protected by at least the dielectric barrier and thus no etching occurs of the sacrificial layers from the second fin. The amount of recessing of the sacrificial layers of the first fin dictates the width of the inner spacer structures that will be formed for the devices of the first fin. In some examples, the sacrificial layers may be recessed to a first lateral depth that is substantially the same as a lateral width of the spacer structures.

Method 1900 continues with operation 1914 where first inner spacers are formed within the recessed portions of the sacrificial layers and first source or drain regions are formed from the ends of the semiconductor layers of the first fin. The first inner spacers may have a material composition that is similar to or the exact same as the spacer structures. The first inner spacers may be conformally deposited over the sides of the fin structure using a CVD process like ALD and then etched back using an isotropic etching process to expose the ends of the semiconductor layers of the first fin. The first source or drain regions may be epitaxially grown from the exposed ends of the semiconductor layers of the first fin, according to some embodiments. Any of the first source or drain regions can act as either a source or drain depending on the application. According to some embodiments, the composition and doping of the first source or drain regions may be the same, such that the first source or drain regions are all n-type regions or all p-type regions.

Method 1900 continues with operation 1916 where the dielectric barrier is removed over the second fin and the revealed portions of the second fin are removed between the sacrificial gate and spacer structures. Another mask structure may be formed over the first fin to protect it during the processing of the second fin. According to some embodiments, the various alternating material layers of the second fin are etched together using an anisotropic RIE process. The RIE process may also etch into the substrate thus recessing portions of the substrate on either side of any of the fin structures.

Method 1900 continues with operation 1918 where another isotropic and selective etch process is used to laterally etch the sacrificial layers of the second fin to a second lateral depth. The amount of recessing of the sacrificial layers of the second fin dictates the width of the inner spacer structures that will be formed for the devices of the second fin. In some examples, the sacrificial layers may be recessed to a second lateral depth that is less than the first lateral depth from the first fin.

Method 1900 continues with operation 1920 where second inner spacers are formed within the recessed portions of the sacrificial layers and second source or drain regions are formed from the ends of the semiconductor layers of the second fin. The second inner spacers may have a material composition that is similar to or the exact same as the spacer structures and/or the first inner spacers. The second inner spacers may be conformally deposited over the sides of the fin structure using a CVD process like ALD and then etched back using an isotropic etching process to expose the ends of the semiconductor layers of the second fin. The second source or drain regions may be epitaxially grown from the exposed ends of the semiconductor layers of the second fin, according to some embodiments. Any of the second source or drain regions can act as either a source or drain depending on the application. According to some embodiments, the composition and doping of the second source or drain regions may be the same, such that the second source or drain regions are all n-type regions or all p-type regions. In one example, the first source or drain regions are all n-type regions and the second source or drain regions are all p-type regions.

Method 1900 continues with operation 1922 where the sacrificial gates are removed and replaced with gate structures. The sacrificial gates are first removed along with any sacrificial layers within the exposed fins between the spacer structures. According to some embodiments, the gate structures extend across the semiconductor material (e.g., semiconductor nanoribbons) of both the first and the second fins. Due to the difference in inner spacer width, the gate structures have a first gate length around the semiconductor material of the first fins and a second gate length around the semiconductor material of the second fins that is greater than the first gate length.

The gate structures may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

### Example System

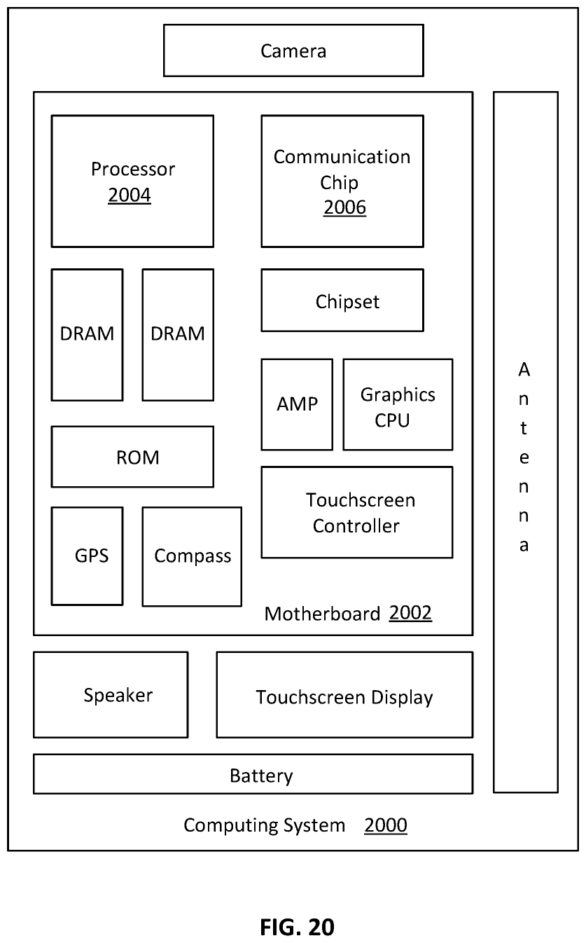

FIG. 20 is an example computing system implemented with one or more of the integrated circuit structures as disclosed herein, in accordance with some embodiments of the present disclosure. As can be seen, the computing system 2000 houses a motherboard 2002. The motherboard 2002 may include a number of components, including, but not limited to, a processor 2004 and at least one communication chip 2006, each of which can be physically and electrically coupled to the motherboard 2002, or otherwise integrated therein. As will be appreciated, the motherboard 2002 may be, for example, any printed circuit board (PCB), whether a main board, a daughterboard mounted on a main board, or the only board of system 2000, etc.

Depending on its applications, computing system 2000 may include one or more other components that may or may not be physically and electrically coupled to the motherboard 2002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2000 may include one or more integrated circuit structures or devices configured in accordance with an example embodiment (e.g., a module including an integrated circuit on a substrate, the substrate having GAA semiconductor devices with different gate lengths, as variously provided herein). In some embodiments, multiple functions can be integrated into one or more chips (e.g., for instance, note that the communication chip 2006 can be part of or otherwise integrated into the processor 2004).

The communication chip 2006 enables wireless communications for the transfer of data to and from the computing system 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

The processor 2004 of the computing system 2000 includes an integrated circuit die packaged within the processor 2004. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 2006 also may include an integrated circuit die packaged within the communication chip 2006. In accordance with some such example embodiments, the integrated circuit die of the communication chip includes one or more semiconductor devices as variously described herein. As will be appreciated in light of this disclosure, note that multi-standard wireless capability may be integrated directly into the processor 2004 (e.g., where functionality of any chips 2006 is integrated into processor 2004, rather than having separate communication chips). Further note that processor 2004 may be a chip set having such wireless capability. In short, any number of processor 2004 and/or communication chips 2006 can be used. Likewise, any one chip or chip set can have multiple functions integrated therein.

In various implementations, the computing system 2000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 2000 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device having at least one first semiconductor body extending in a first direction from a first source or drain region, a first gate structure extending in a second direction over the first semiconductor body and wrapped around the first semiconductor body, and at least one first dielectric spacer between the first gate structure and the first source or drain region. The integrated circuit also includes a second semiconductor device having at least one second semiconductor body extending in the first direction from a second source or drain region, a second gate structure extending in the second direction over the at least one second semiconductor body and wrapped around the second semiconductor body, and at least one second dielectric spacer between the second gate structure and the second source or drain region. The at least one first dielectric spacer is at least 2 nm longer than the at least one second dielectric spacer along the first direction.

Example 2 includes the integrated circuit of Example 1, wherein the at least one first semiconductor body and the at least one second semiconductor body comprise germanium, silicon, or a combination thereof.

Example 3 includes the integrated circuit of Example 1 or 2, wherein the at least one first semiconductor body and the at least one second semiconductor body are coplanar on a plane extending in both the first and second directions.

Example 4 includes the integrated circuit of any one of Examples 1-3, wherein the at least one first dielectric spacer is over an end of the at least one first semiconductor body, and the at least one second dielectric spacer is over an end of the at least one second semiconductor body.

Example 5 includes the integrated circuit of any one of Examples 1-4, wherein the first gate structure has a first gate length over the at least one first semiconductor body along the first direction and the second gate structure has a second gate length over the at least one second semiconductor body along the first direction, the first gate length being at least 4 nm less than the second gate length.

Example 6 includes the integrated circuit of any one of Examples 1-5, wherein the first semiconductor device further comprises a first gate spacer over the at least one first dielectric spacer and on a sidewall of the first gate structure, and the second semiconductor device further comprises a second gate spacer over the at least one second dielectric spacer and on a sidewall of the second gate structure.

Example 7 includes the integrated circuit of Example 6, wherein the first gate spacer and the second gate spacer have substantially the same lateral thickness along the first direction.

Example 8 includes the integrated circuit of Example 7, wherein the lateral thickness of the first gate spacer is within 10 angstroms of the lateral thickness of the second gate spacer.

Example 9 includes the integrated circuit of any one of Examples 6-8, wherein the first gate spacer and the at least one first dielectric spacer comprise substantially the same dielectric material, and the second gate spacer and the at least one second dielectric spacer comprise substantially the same dielectric material.

Example 10 includes the integrated circuit of any one of Examples 1-9, wherein the first semiconductor device further comprises a first contact on the first source or drain region, and the second semiconductor device further comprises a second contact on the second source or drain region. The first gate structure has a first thickness along the first direction and laterally adjacent to the first contact, and the second gate structure has a second thickness along the first direction and laterally adjacent to the second contact with the first thickness being within 1 nm of the second thickness. The first gate structure has a first gate length along the first direction and laterally adjacent to the at least one first dielectric spacer, and the second gate structure has a second gate length along the first direction and laterally adjacent to the at least one second dielectric spacer with the first gate length being at least 4 nm less than the second gate length.

Example 11 includes the integrated circuit of Example 10, wherein the first semiconductor device further comprises a first gate spacer laterally between the first contact and the first gate structure, and the second semiconductor device further comprises a second gate spacer laterally between the second contact and the second gate structure.

Example 12 includes the integrated circuit of Example 11, wherein the first gate spacer has a third thickness along the first direction and laterally adjacent to the first contact, and the second gate spacer has a fourth thickness along the first direction and laterally adjacent to the second contact, the third thickness being within 1 nm of the fourth thickness.

Example 13 is a printed circuit board that includes the integrated circuit of any one of Examples 1-12.

Example 14 is an electronic device that includes a chip package having one or more dies. At least one of the one or more dies includes a first semiconductor device having a plurality of first semiconductor nanoribbons extending in a first direction from a first source or drain region, a first gate structure extending in a second direction over the plurality of first semiconductor nanoribbons, and at least one first dielectric spacer between the first gate structure and the first source or drain region. The integrated circuit also includes a second semiconductor device having a plurality of second semiconductor nanoribbons extending in the first direction from a second source or drain region, a second gate structure extending in the second direction over the plurality of second semiconductor nanoribbons, and at least one second dielectric spacer between the second gate structure and the second source or drain region. The at least one first dielectric spacer is at least 2 nm longer than the at least one second dielectric spacer along the first direction.

Example 15 includes the electronic device of Example 14, wherein the plurality of first semiconductor nanoribbons and the plurality of second semiconductor nanoribbons comprise germanium, silicon, or a combination thereof.

Example 16 includes the electronic device of Example 14 or 15, wherein a first given nanoribbon of the plurality of first semiconductor nanoribbons and a second given nanoribbon of the plurality of second semiconductor nanoribbons are substantially coplanar on a plane extending in both the first and second directions.

Example 17 includes the electronic device of any one of Examples 14-16, wherein the at least one first dielectric spacer is between ends of two nanoribbons of the plurality of first semiconductor nanoribbons along a third direction, and the at least one second dielectric spacer is between ends of two nanoribbons of the plurality of second semiconductor nanoribbons along the third direction.

Example 18 includes the electronic device of any one of Examples 14-17, wherein the first gate structure has a first gate length over the plurality of first semiconductor nanoribbons along the first direction and the second gate structure has a second gate length over the plurality of second semiconductor nanoribbons along the first direction, the first gate length being at least 4 nm greater than the second gate length.

Example 19 includes the electronic device of any one of Examples 14-18, wherein the first semiconductor device further comprises a first gate spacer over the at least one first dielectric spacer and on a sidewall of the first gate structure, and the second semiconductor device further comprises a second gate spacer over the at least one second dielectric spacer and on a sidewall of the second gate structure.

Example 20 includes the electronic device of Example 19, wherein the first gate spacer and the second gate spacer have substantially the same lateral thickness along the first direction.

Example 21 includes the electronic device of Example 19 or 20, wherein the first gate spacer and the at least one first dielectric spacer comprise substantially the same dielectric material, and the second gate spacer and the at least one second dielectric spacer comprise substantially the same dielectric material.

Example 22 includes the electronic device of any one of Examples 14-21, further comprising a printed circuit board, wherein the chip package is coupled to the printed circuit board.

Example 23 includes a method of forming an integrated circuit. The method includes forming a first fin comprising first semiconductor layers alternating with first sacrificial layers, the first fin extending above a substrate and extending in a first direction; forming a second fin comprising second semiconductor layers alternating with second sacrificial layers, the second fin extending above a substrate and extending in the first direction; forming a dielectric structure over the first fin and the second fin; forming a mask structure over the second fin; removing a portion of the dielectric structure and a portion of the first fin such that the first semiconductor layers alternating with first sacrificial layers are exposed; performing a first etch process to laterally recess the first sacrificial layers and form first laterally recessed areas having a first recess depth along the first direction; forming first dielectric spacer structures within the first laterally recessed areas; forming a first source or drain region from exposed ends of the first semiconductor layers; removing the mask structure over the second fin; removing a portion of the dielectric structure and a portion of the second fin such that the second semiconductor layers alternating with second sacrificial layers are exposed; performing a second etch process to laterally recess the second sacrificial layers and form second laterally recessed areas having a second recess depth along the first direction that is different from the first recess depth by at least 2 nm; forming second dielectric spacer structures within the second laterally recessed areas; and forming a second source or drain region from exposed ends of the second semiconductor layers.

Example 24 includes the method of Example 23, further comprising forming a sacrificial gate structure crossing over the first fin and the second fin along a second direction. Forming the dielectric structure comprises forming the dielectric structure on sidewalls of the sacrificial gate structure.

Example 25 includes the method of Example 24, further comprising removing the sacrificial gate structure and the first and second sacrificial layers and forming a gate structure over the first and second semiconductor layers.

Example 26 includes the method of any one of Examples 23-25, wherein forming the first source or drain region comprises forming an n-type source or drain region and forming the second source or drain region comprises forming a p-type source or drain region.

Example 27 includes the method of any one of Examples 23-25, wherein forming the first source or drain region comprises forming a p-type source or drain region and forming the second source or drain region comprises forming an n-type source or drain region.

Example 28 is an integrated circuit that includes a first semiconductor device having a plurality of first semiconductor nanoribbons extending in a first direction from a first source or drain region to a second source or drain region, a first gate structure extending in a second direction over the plurality of first semiconductor nanoribbons, and a plurality of first dielectric spacers between the first gate structure and the first source or drain region and between the first gate structure and the second source or drain region. The integrated circuit also includes a second semiconductor device having a plurality of second semiconductor nanoribbons extending in the first direction from a third source or drain region to a fourth source or drain region, a second gate structure extending in the second direction over the plurality of second semiconductor nanoribbons, and a plurality of second dielectric spacers between the second gate structure and the third source or drain region and between the second gate structure and the fourth source or drain region. The plurality of first dielectric spacers are at least 2 nm longer than the plurality of second dielectric spacers along the first direction.

Example 29 includes the integrated circuit of Example 28, wherein the plurality of first semiconductor nanoribbons and the plurality of second semiconductor nanoribbons comprise germanium, silicon, or a combination thereof.

Example 30 includes the integrated circuit of Example 28 or 29, wherein each of the plurality of first dielectric spacers is over an end of a corresponding nanoribbon of the plurality of first semiconductor nanoribbons, and each of the plurality of second dielectric spacers is over an end of a corresponding nanoribbon of the plurality of second semiconductor nanoribbons.

Example 31 includes the integrated circuit of any one of Examples 28-30, wherein the first gate structure has a first gate length over the plurality of first semiconductor nanoribbons along the first direction and the second gate structure has a second gate length over the plurality of second semiconductor nanoribbons along the first direction, the first gate length being at least 4 nm greater than the second gate length.

Example 32 includes the integrated circuit of any one of Examples 28-31, wherein the first semiconductor device further comprises a first gate spacer over the plurality of first dielectric spacers and on a sidewall of the first gate structure, and the second semiconductor device further comprises a second gate spacer over the plurality of second dielectric spacers and on a sidewall of the second gate structure.

Example 33 includes the integrated circuit of Example 32, wherein the first gate spacer and the second gate spacer have substantially the same lateral thickness along the first direction.

Example 34 includes the integrated circuit of Example 32 or 33, wherein the first gate spacer and the plurality of first dielectric spacers comprise substantially the same dielectric material, and the second gate spacer and the plurality of second dielectric spacers comprise substantially the same dielectric material.

Example 35 is a printed circuit board that includes the integrated circuit of any one of Examples 28-34.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having at least one first semiconductor body extending in a first direction from a first source or drain region, a first gate structure extending in a second direction over the first semiconductor body, and at least one first dielectric spacer between the first gate structure and the first source or drain region; and
a second semiconductor device having at least one second semiconductor body extending in the first direction from a second source or drain region, a second gate structure extending in the second direction over the at least one second semiconductor body, and at least one second dielectric spacer between the second gate structure and the second source or drain region;
wherein the at least one first dielectric spacer is at least 2 nm longer than the at least one second dielectric spacer along the first direction.

2. The integrated circuit of claim 1, wherein the at least one first semiconductor body and the at least one second semiconductor body are coplanar on a plane extending in both the first and second directions.

3. The integrated circuit of claim 1, wherein the at least one first dielectric spacer is over an end of the at least one first semiconductor body, and the at least one second dielectric spacer is over an end of the at least one second semiconductor body.

4. The integrated circuit of claim 1, wherein the first gate structure has a first gate length over the at least one first semiconductor body along the first direction and the second gate structure has a second gate length over the at least one second semiconductor body along the first direction, the first gate length being at least 4 nm less than the second gate length.

5. The integrated circuit of claim 1, wherein the first semiconductor device further comprises a first gate spacer over the at least one first dielectric spacer and on a sidewall of the first gate structure, and the second semiconductor device further comprises a second gate spacer over the at least one second dielectric spacer and on a sidewall of the second gate structure.

6. The integrated circuit of claim 5, wherein the lateral thickness of the first gate spacer is within 10 angstroms of the lateral thickness of the second gate spacer.

7. The integrated circuit of claim 1, wherein:
the first semiconductor device further comprises a first contact on the first source or drain region; and
the second semiconductor device further comprises a second contact on the second source or drain region;
wherein the first gate structure has a first thickness along the first direction and laterally adjacent to the first contact, the second gate structure has a second thickness along the first direction and laterally adjacent to the second contact, the first thickness being within 1 nm of the second thickness; and
wherein the first gate structure has a first gate length along the first direction and laterally adjacent to the at least one first dielectric spacer, and the second gate structure has a second gate length along the first direction and laterally adjacent to the at least one second dielectric spacer, the first gate length being at least 4 nm less than the second gate length.

8. A printed circuit board comprising the integrated circuit of claim 1.

9. An electronic device, comprising:
a chip package comprising one or more dies, at least one of the one or more dies comprising
a first semiconductor device having a plurality of first semiconductor nanoribbons extending in a first direction from a first source or drain region, a first gate structure extending in a second direction over the plurality of first semiconductor nanoribbons, and at least one first dielectric spacer between the first gate structure and the first source or drain region; and
a second semiconductor device having a plurality of second semiconductor nanoribbons extending in the first direction from a second source or drain region, a second gate structure extending in the second direction over the plurality of second semiconductor nanoribbons, and at least one second dielectric spacer between the second gate structure and the second source or drain region;
wherein the first dielectric spacer is at least 2 nm longer than the second dielectric spacer along the first direction.

10. The electronic device of claim 9, wherein a first given nanoribbon of the plurality of first semiconductor nanoribbons and a second given nanoribbon of the plurality of second semiconductor nanoribbons are substantially coplanar on a plane extending in both the first and second directions.

11. The electronic device of claim 9, wherein the at least one first dielectric spacer is between ends of two nanoribbons of the plurality of first semiconductor nanoribbons along a third direction, and the at least one second dielectric spacer is between ends of two nanoribbons of the plurality of second semiconductor nanoribbons along the third direction.

12. The electronic device of claim 9, wherein the first gate structure has a first gate length over the plurality of first semiconductor nanoribbons along the first direction and the second gate structure has a second gate length over the plurality of second semiconductor nanoribbons along the first direction, the first gate length being at least 4 nm greater than the second gate length.

13. The electronic device of claim 9, wherein the first semiconductor device further comprises a first gate spacer over the at least one first dielectric spacer and on a sidewall of the first gate structure, and the second semiconductor device further comprises a second gate spacer over the at least one second dielectric spacer and on a sidewall of the second gate structure.

14. The electronic device of claim 13, wherein the first gate spacer and the second gate spacer have substantially the same lateral thickness along the first direction.

15. An integrated circuit comprising:
a first semiconductor device having a plurality of first semiconductor nanoribbons extending in a first direction from a first source or drain region to a second source or drain region, a first gate structure extending in a second direction over the plurality of first semiconductor nanoribbons, and a plurality of first dielectric spacers between the first gate structure and the first source or drain region and between the first gate structure and the second source or drain region; and
a second semiconductor device having a plurality of second semiconductor nanoribbons extending in the first direction from a third source or drain region to a fourth source or drain region, a second gate structure extending in the second direction over the plurality of second semiconductor nanoribbons, and a plurality of second dielectric spacers between the second gate structure and the third source or drain region and between the second gate structure and the fourth source or drain region;
wherein the plurality of first dielectric spacers are at least 2 nm longer than the plurality of second dielectric spacers along the first direction.

16. The integrated circuit of claim 15, wherein each of the plurality of first dielectric spacers is over an end of a corresponding nanoribbon of the plurality of first semiconductor nanoribbons, and each of the plurality of second dielectric spacers is over an end of a corresponding nanoribbon of the plurality of second semiconductor nanoribbons.

17. The integrated circuit of claim 15, wherein the first gate structure has a first gate length over the plurality of first semiconductor nanoribbons along the first direction and the second gate structure has a second gate length over the plurality of second semiconductor nanoribbons along the first direction, the first gate length being at least 4 nm greater than the second gate length.

18. The integrated circuit of claim 15, wherein the first semiconductor device further comprises a first gate spacer over the plurality of first dielectric spacers and on a sidewall of the first gate structure, and the second semiconductor device further comprises a second gate spacer over the plurality of second dielectric spacers and on a sidewall of the second gate structure.

19. The integrated circuit of claim 18, wherein the first gate spacer and the second gate spacer have substantially the same lateral thickness along the first direction.

20. The integrated circuit of claim 18, wherein the first gate spacer and the plurality of first dielectric spacers comprise substantially the same dielectric material, and the second gate spacer and the plurality of second dielectric spacers comprise substantially the same dielectric material.
